(19) United States
(12) Patent Application Publication
(10) Pub. No.: US 2026/0173532 A1
(43) Pub. Date: Jun. 18, 2026

(54) TRANSISTOR CIRCUIT WITH LOW-INDUCTANCE ODD-MODE RESISTORS

(71) Applicant: NXP USA, Inc., AUSTIN, TX (US)

(72) Inventors: Jitesh Vaswani, Gilbert, AZ (US); Olivier Lembeye, Saint Lys (FR); Raphael Holin, Toulouse (FR); Aniket Anant Wadodkar, Gilbert, AZ (US); Seungkee Min, Chandler, AZ (US); David Cobb Burdeaux, Tempe, AZ (US); Sai Sunil Mangaonkar, Chandler, AZ (US)

(21) Appl. No.: 19/265,074

(22) Filed: Jul. 10, 2025

(30) Foreign Application Priority Data
Dec. 12, 2024 (EP) 24307086.9

(51) Int. Cl. H10D 89/10; H01L 23/00; H01L 23/522; H10D 80/20; H10D 84/80

(52) U.S. Cl. CPC H10D 89/10; H10D 80/213; H10D 80/251; H10D 84/811; H10W 20/42; H10W 72/921; H10W 72/926; H10W 72/9445

(57) ABSTRACT

A transistor includes a semiconductor die, first and second transistor fingers formed in an active area of the semiconductor die, a first bond pad segment formed in the semiconductor die and electrically coupled to the first transistor finger, a second bond pad segment formed in the semiconductor die and electrically coupled to the second transistor finger, and a first odd-mode resistor circuit electrically coupled to the first and second bond pad segments. The second bond pad segment is adjacent to the first bond pad segment, and a first non-conductive gap is present between the first and second bond pad segments. The first odd-mode resistor circuit has a first resistor segment and a second resistor segment. The first and second resistor segments are arranged next to each other and oriented in parallel.

### CROSS-REFERENCE TO RELATED APPLICATIONS

This application claims priority under 35 U.S.C. § 119 to European patent application no. 24307086.9, filed 12 Dec. 2024, the contents of which are incorporated by reference herein.

### TECHNICAL FIELD OF THE INVENTION

The present invention relates generally to transistors. More specifically, the present invention relates to a transistor layout utilizing a circuit configured to stabilize odd-mode oscillations in the transistor during operation.

### BACKGROUND OF THE INVENTION

Radio Frequency (RF) power transistors that are sufficiently large relative to the wavelength of their maximum frequency of operation may be vulnerable to DC-IV oscillations that may lead to odd-mode instability. Odd-mode instability is a phenomenon in which an undesirable oscillation becomes established in the transistor due to high odd-mode loop currents. This oscillation can be viewed as an oscillating signal being amplified as it travels laterally from one end of the device to the other end and then back, reinforcing itself with each round trip. Besides just physical size and maximum operating frequency, other factors also can be relevant to whether significant odd-mode oscillations will occur within a transistor. In order to reduce or eliminate detrimental effects on transistor performance associated with odd-mode oscillations and odd-mode instability, designers strive to design transistors in which odd-mode instability is less likely to occur.

### BRIEF DESCRIPTION OF THE DRAWINGS

The accompanying figures in which like reference numerals refer to identical or functionally similar elements throughout the separate views, the figures are not necessarily drawn to scale, and which together with the detailed description below are incorporated in and form part of the specification, serve to further illustrate various embodiments and to explain various principles and advantages all in accordance with the present invention.

FIG. 1 is a schematic of a field effect transistor (FET) circuit configuration with segmented gate and drain bond pads and low-inductance odd-mode resistors, in accordance with an example embodiment;

FIG. 2 is a top view of a FET with segmented gate and drain bond pads and various example embodiments of low-inductance odd-mode resistors;

FIG. 3 is a top view of an enlarged portion of the FET of FIG. 2;

FIG. 4 is an example of an embodiment of a mutual-inductance odd-mode resistor;

FIG. 5A is a cross-sectional view of an embodiment of the mutual-inductance odd-mode resistor of FIG. 4 through line 5-5 for an embodiment of the low-inductance odd-mode resistor;

FIG. 5B is a cross-sectional view of another embodiment of the mutual-inductance odd-mode resistor of FIG. 4 through line 5-5;

FIG. 6A is a cross-sectional view of another embodiment of the parallel-coupled odd-mode resistor of FIG. 4 through line 6-6;

FIG. 6B is a cross-sectional view of another embodiment of the parallel-coupled resistor of FIG. 4 through line 6-6;

FIG. 7 is an example of an embodiment of a parallel-coupled odd-mode resistor;

FIG. 8A is a cross-sectional view of the parallel-coupled odd-mode resistor of FIG. 7 through line 8-8;

FIG. 8B is a cross-sectional view of an embodiment of the parallel-coupled odd-mode resistor of FIG. 7 through line 8-8;

FIG. 9A is a cross-sectional view of another embodiment of the parallel-coupled odd-mode resistor of FIG. 7 through line 9-9;

FIG. 9B is a cross-sectional view of another embodiment of the parallel-coupled odd-mode resistor of FIG. 7 through line 9-9;

FIG. 10 is an example of an embodiment of a 2^{N}-terminal odd-mode resistor;

FIG. 11A is a cross-sectional view of the 2^{N}-terminal odd-mode resistor of FIG. 10 through line 11-11;

FIG. 11B is a cross-sectional view of the 2^{N}-terminal odd-mode resistor of FIG. 10 through line 11-11;

FIG. 12 is a top view of a portion of a FET with segmented gate and drain bond pads and additional example embodiments of low-inductance odd-mode resistors;

FIG. 13 is an example of another embodiment of a mutual-inductance odd-mode resistor;

FIG. 14 is a cross-sectional view of the mutual-inductance odd-mode resistor of FIG. 13 through line 14-14;

FIG. 15 is a cross-sectional view of the mutual-inductance odd-mode resistor of FIG. 13 through line 15-15;

FIG. 16 is a cross-sectional view of the parallel-coupled odd-mode resistor of FIG. 12 through line 16-16;

FIG. 17 is a top view of another embodiment of a mutual-inductance odd-mode resistor;

FIG. 18 is a top view of yet another embodiment of a mutual-inductance odd-mode resistor;

FIG. 19 is a top view of yet another embodiment of a mutual-inductance odd-mode resistor;

FIG. 20 is a top view of a FET with segmented gate and drain bond pads and various other example embodiments of low-inductance odd-mode resistors;

FIG. 21 is a top view of a FET with segmented gate and drain bond pads and various other example embodiments of low-inductance odd-mode resistors; and

FIG. 22 is a top view of a FET with segmented gate and drain bond pads and various other example embodiments of low-inductance odd-mode resistors.

### DETAILED DESCRIPTION

As discussed above, a radio frequency (RF) power transistor that is sufficiently large relative to the wavelength of its maximum frequency of operation may be vulnerable to odd-mode instability due to odd-mode oscillations that occur during operation. A segmented bond pad and odd-mode resistors may be considered to attempt to achieve odd-mode stability in a transistor. However, the parasitic inductance of any odd-mode resistor may negatively affect the odd-mode stability, with higher parasitic inductances having more detrimental impacts on performance. As will be described in detail below, embodiments of the inventive subject matter include RF power transistors with segmented gate and/or drain bond pads, along with one or more low-inductance odd-mode resistor circuits positioned between and electrically coupled to adjacent gate bond pad segments and/or drain bond pad segments.

According to one or more embodiments, each odd-mode resistor circuit includes at least two resistor segments that are arranged next to each other and oriented in parallel. As will be explained in detail below, some embodiments include resistor segments that are “physically oriented” in parallel (referred to below as “physically-parallel” resistor segments), while other embodiments include resistor segments that are “electrically coupled” in parallel (referred to below as “electrically-parallel” resistor segments), and still other embodiments include resistor segments that are both physically oriented and electrically coupled in parallel (referred to below as “physically-and electrically-parallel” resistor segments). When the term “parallel” is used in the below description without a qualifying term (e.g., “physically” and/or “electrically”), interpretation of the term “parallel” should be made in the context of the drawings and the particular embodiment being discussed. Either way, including at least two physically-and/or electrically-parallel resistor segments in each odd-mode resistor circuit causes each odd-mode resistor circuit to have lower parasitic inductance, when compared with a single, equivalently-valued resistor that includes only one resistor segment.

As will be explained in more detail below, some embodiments of odd-mode resistor circuits utilize physically-parallel resistor segments that experience negative mutual inductive coupling during operation, and the negative mutual inductive coupling effectively reduces the overall parasitic inductance of the odd-mode resistor circuits. Additionally or alternatively, some embodiments of odd-mode resistor circuits implement a desired effective resistance with two electrically-parallel resistor paths (with each path corresponding to a “resistor segment”), which enables a reduction of the parasitic inductance of the odd-mode resistor circuit to about half of that which would be present if a single odd-mode resistor having the same effective resistance were used. In an RF power transistor, utilizing an embodiment of an odd-mode resistor circuit with reduced parasitic inductance enables the odd-mode resistor circuit to more effectively dampen odd-mode oscillations within the RF power transistor during operation, when compared with conventional RF power transistor designs. Accordingly, embodiments of RF power transistors described herein are better suited to achieve robust odd-mode stability during operation.

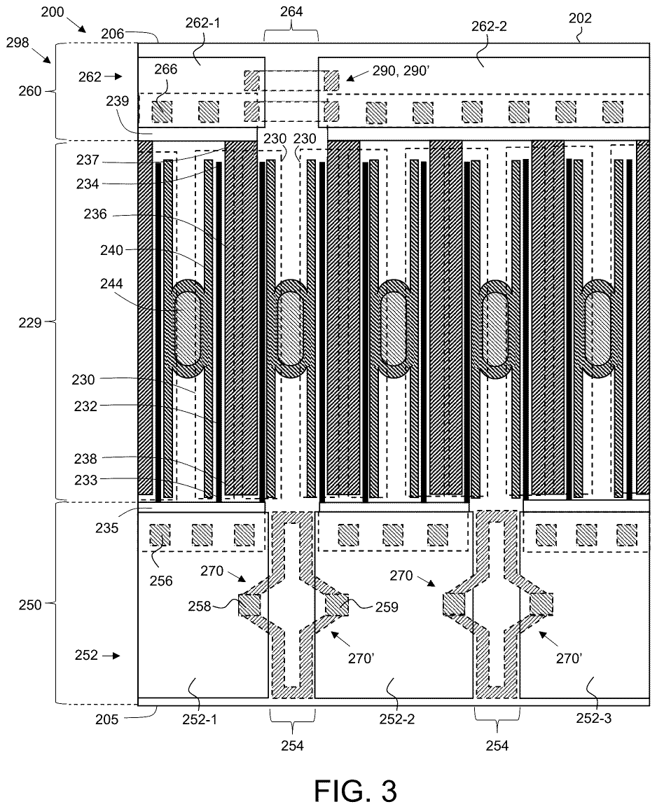

An RF power transistor includes a semiconductor die (e.g., die 202, FIG. 2) with a plurality of transistor fingers (e.g., transistor fingers 230, FIG. 3). Each transistor finger includes an elongated source structure (e.g., source structure 240, FIG. 3) adjacent to but spatially separated from an elongated drain structure (e.g., drain structure 236, FIG. 3), where an elongated channel region is located between the source and drain structures. The source structures are electrically connected to a ground reference. An elongated gate structure (e.g., gate structure 232, FIG. 3) overlies each channel region. During operation of the RF power transistor, an RF signal applied to each gate structure varies the electrical conductivity of the channel that it overlies, thus varying the amount of current flowing between adjacent source and drain regions.

According to one or more embodiments, proximal ends of the gate structures are electrically coupled to a segmented gate bond pad (e.g., segmented gate bond pad 252, FIG. 2). More particularly, the proximal end of each gate structure is electrically coupled to a gate bond pad segment (e.g., one of gate bond pad segments 252-1 through 252-6, FIG. 2). During operation, the segmented gate bond pad is configured to receive an input RF signal for amplification, and to convey that signal to the gate structures. As will be discussed in detail below, one or more embodiments of RF power transistors include unique odd-mode resistor circuits coupled between the gate bond pad segments. These embodiments of odd-mode resistor circuits are characterized by resistance values that are sufficient to dampen odd-mode loop currents, while having parasitic inductance values that are sufficiently low as to ensure adequate odd-mode stability.

According to one or more further embodiments, proximal ends of the drain regions are electrically coupled to a segmented drain bond pad (e.g., segmented drain bond pad 262, FIG. 2). More particularly, the proximal end of each drain region is electrically coupled to a drain bond pad segment (e.g., one of drain bond pad segments 262-1 through 262-3, FIG. 2). During operation, the segmented drain bond pad is configured to receive amplified RF signals from the drain regions, and the cumulative amplified RF signals received by the segmented drain bond pad correspond to an amplified output RF signal produced by the RF power transistor. As will be discussed in detail below, one or more embodiments of RF power transistors also or alternatively include unique odd-mode resistor circuits coupled between the drain bond pad segments. Again, these embodiments of odd-mode resistor circuits are characterized by resistance values that are sufficient to dampen odd-mode loop currents, while having parasitic inductance values that are sufficiently low as to ensure adequate odd-mode stability.

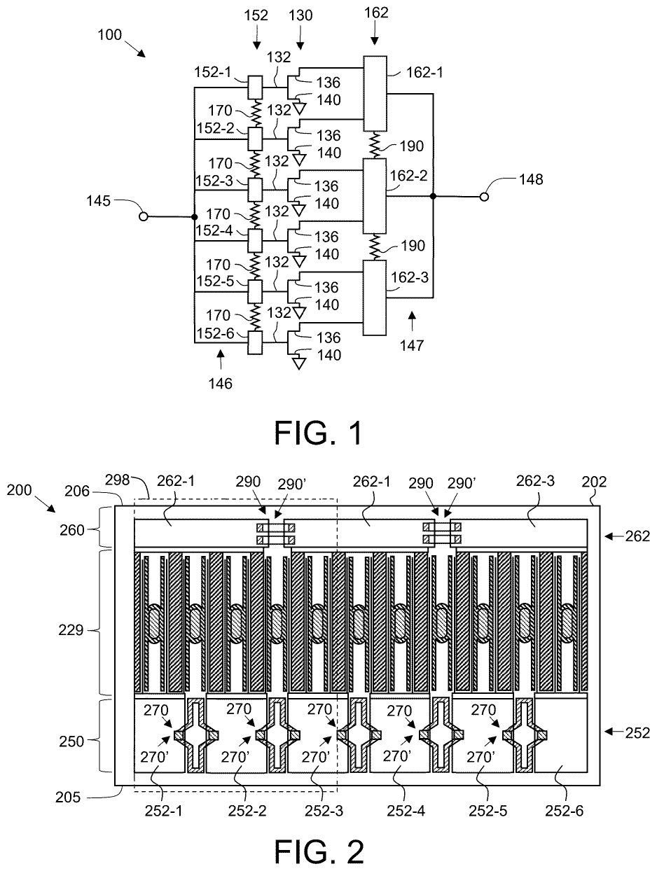

FIG. 1 is a schematic of an RF power transistor in the form of a field-effect transistor (FET) 100, which has an input terminal 145, an output terminal 148, and a plurality of transistor fingers 130 electrically coupled between the input and output terminals 145, 148. Each transistor finger 130 includes a gate 132 (or “gate structure”), a drain 136 (or “drain structure”), and a source 140 (or “source structure”). FET 100 has a “common source configuration,” in which each source structure 140 is electrically coupled to a ground reference (e.g., system ground), as shown in FIG. 1.

As discussed above, RF power FETs that are sufficiently large relative to the wavelength of their maximum frequency of operation may be vulnerable to odd-mode instability due to odd-mode oscillations that occur during operation. To dampen (i.e., reduce the signal energy of) the odd-mode oscillations, FET 100 also includes a segmented gate bond pad 152 and a segmented drain bond pad 162. The segmented gate bond pad 152 includes a plurality of gate bond pad segments 152-1, 152-2, 152-3, 152-4, 152-5, 152-6, each of which is electrically coupled (e.g., through connections 146) to the input terminal 145 of the FET 100. In addition, each gate bond pad segment 152-1 through 152-6 is electrically coupled to a gate 132 of a transistor finger 130. In other embodiments, the gates 132 of multiple transistor cells 130 may be connected to any particular gate bond pad segment 152-1 through 152-6.

The segmented drain bond pad 162 includes a plurality of drain bond pad segments 162-1, 162-2, 162-3, each of which is electrically coupled (e.g., through connections 147) to the output terminal 148 of the FET 100. In addition, each drain bond pad segment 162-1 through 162-3 is electrically coupled to two drains 136 of two adjacent transistor fingers 130. In other embodiments, only one drain 136 or more than two drains 136 may be connected to any particular drain bond pad segment 162-1 through 162-3.

According to one or more embodiments, first odd-mode resistor circuits 170 are electrically coupled between sets of adjacent gate bond pad segments 152-1 through 152-6, and second odd-mode resistor circuits 190 are electrically coupled between sets of adjacent drain bond pad segments 162-1 through 162-3. As used herein, the term “adjacent” means “physically next to.” During operation, the first and second odd-mode circuits 152-1 through 152-6, 162-1 through 162-3 function to dissipate the energy of signals traveling laterally within the FET 100 (i.e., signals traveling in a direction that is perpendicular to a line drawn between the input and output terminals 145, 148), while having little or no impact on the intended signal for amplification.

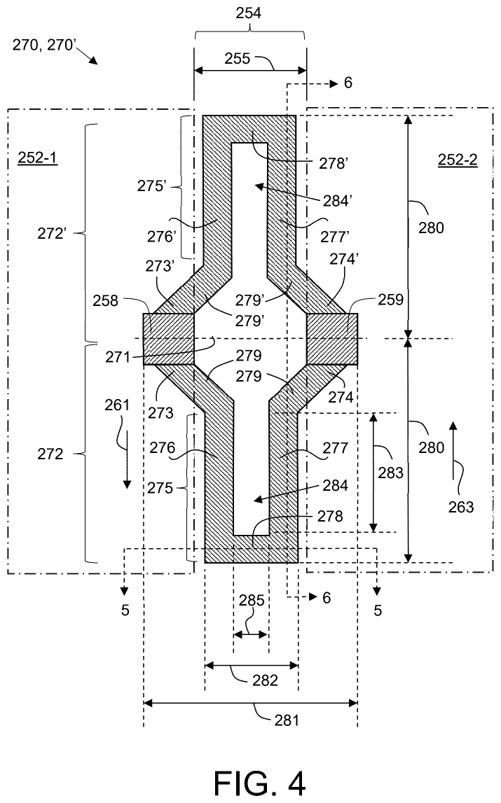

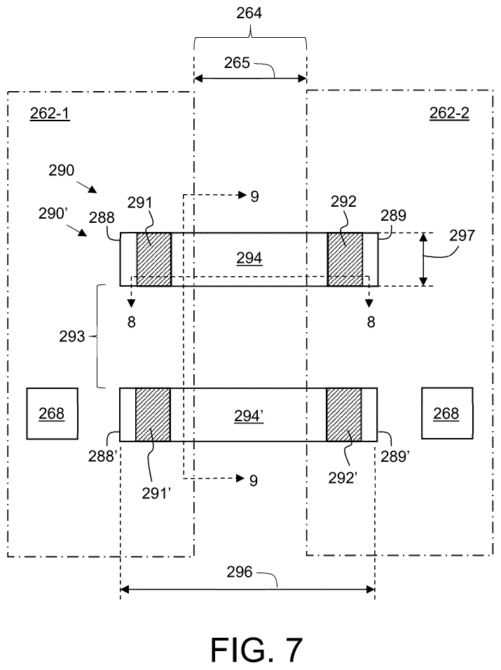

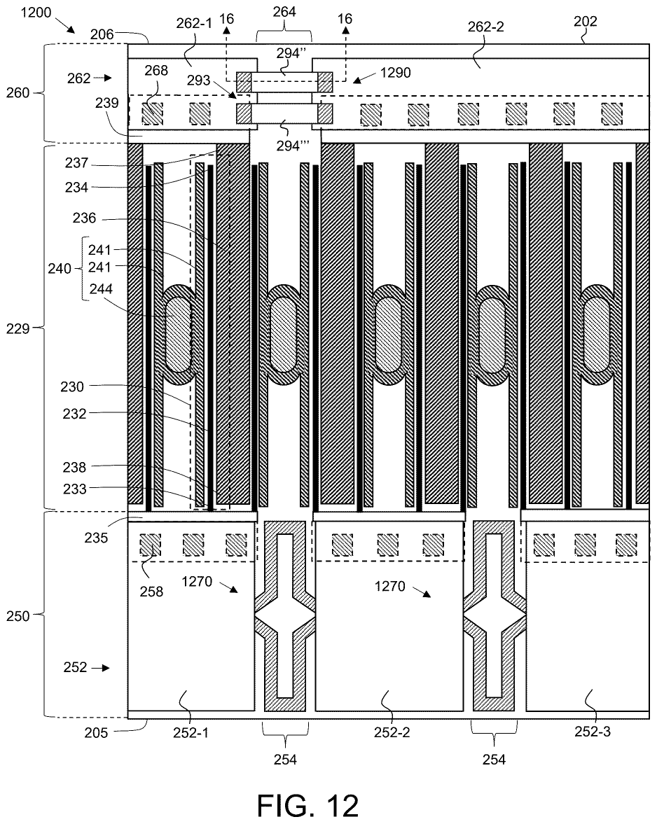

According to one or more further embodiments, some or all of the first and second odd-mode circuits 170, 190 include a first resistor segment (e.g., resistor segment 276, 276′, FIG. 4) and a second resistor segment (e.g., resistor segment 277, 277′, FIG. 4), where the first and second resistor segments are arranged next to each other and physically oriented in parallel. According to one or more other embodiments, some or all of the first and second odd-mode circuits 170, 190 include a first resistor segment (e.g., resistor segment 294, 294″, FIGS. 7, 12) and a second resistor segment (e.g., resistor segment 294′, 294′″, FIGS. 7, 12), where the first and second resistor segments are arranged next to each other and electrically coupled in parallel. This configuration for the first and second odd-mode circuits 170, 190 results in a resistive connection between adjacent bond pad segments that has lower inductance, when compared with a resistive connection that includes only one resistor segment. As indicated above, utilizing odd-mode resistor circuits 170, 190 with comparatively-low parasitic inductance enables the odd-mode resistor circuits 170, 190 to more effectively dampen odd-mode oscillations within FET 100 during operation, when compared with conventional FETs.

Although FIG. 1 shows an embodiment of a FET 100 that includes a segmented gate bond pad 152 with six gate bond pad segments 152-1 through 152-6 (and five first odd-mode resistors 170), and a segmented drain bond pad 162 with three drain bond pad segments 162-1 through 162-3 (and two second odd-mode resistors 190), other embodiments of FETs may include more or fewer gate bond pad segments, drain bond pad segments, and/or odd-mode resistors.

Various physical embodiments of FET 100 will now be described. The FET 100 of FIG. 1, and variations thereof, may be implemented with a transistor that is integrated within a single semiconductor die. More particularly, the segmented gate bond pad 152, transistor fingers 130, segmented drain bond pad 162, and odd-mode resistor circuits 170, 190 may be implemented between input and output terminals of the semiconductor die.

For example, reference is now made to FIGS. 2-4, 5A, 5B, 6A, 6B, 7, 7A, 7B, 8A, 8B, 9A, and 9B, which show various top, enlarged, and side cross-sectional views of various embodiments of a FET 200, which includes the above-listed transistor features. For enhanced understanding, FIGS. 2-4, 5A, 5B, 6A, 6B, 7, 7A, 7B, 8A, 8B, 9A, and 9B should be viewed simultaneously, and the below description of FET 200 will refer to each of these figures in describing FET 200.

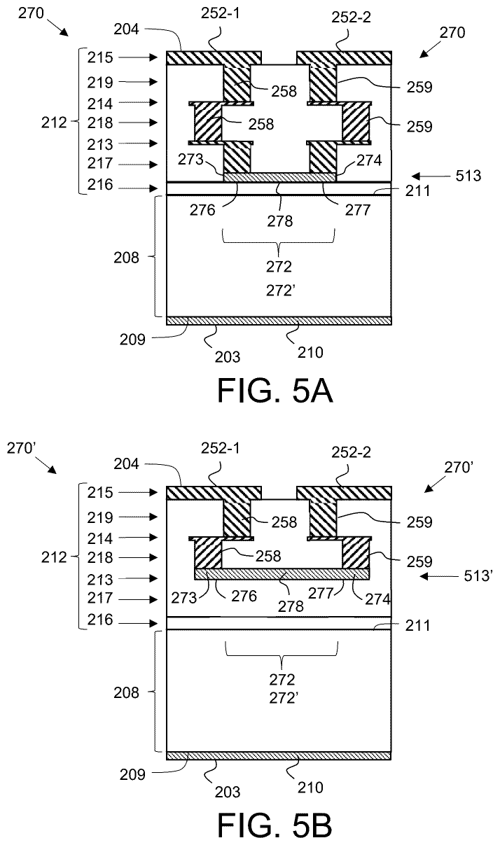

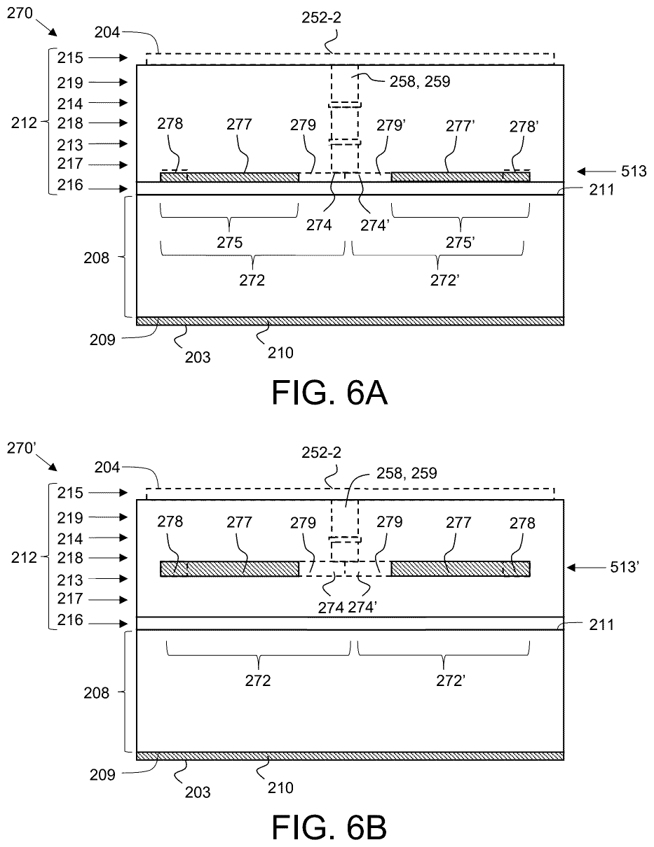

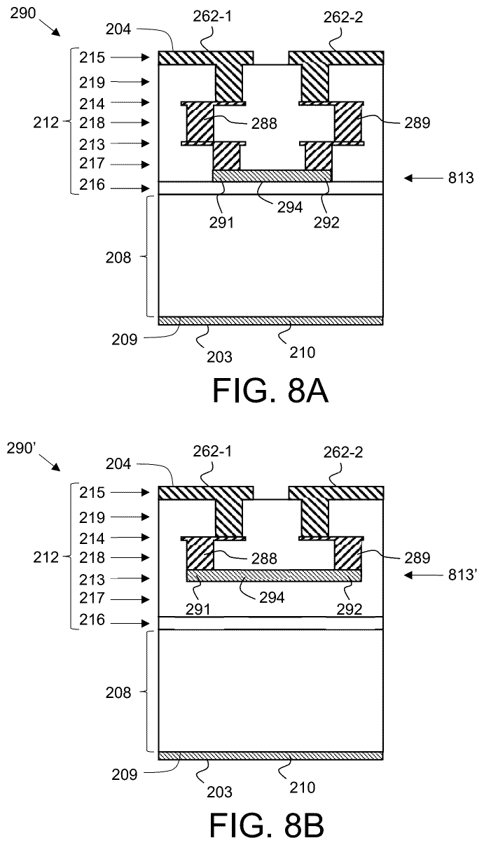

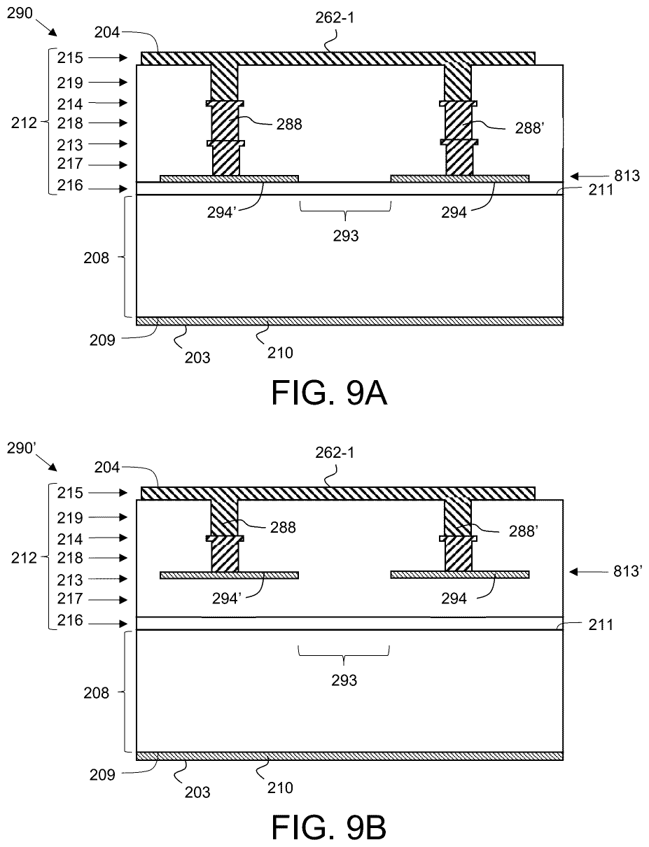

Specifically, FIG. 2 is a top view of a FET 200 with segmented gate and drain bond pads 252, 262, and various example embodiments of low-inductance odd-mode resistor circuits 270, 270′, 290, 290′, and FIG. 3 is a top view of an enlarged portion 298 of the FET 200 of FIG. 2. FIG. 4 is an example of a first low-inductance odd-mode resistor circuit 270, 270′, according to one or more embodiments. FIGS. 5A and 5B are side, cross-sectional views of two embodiments of the odd-mode resistor circuit 270, 270′ of FIG. 4 through line 5-5, and FIGS. 6A and 6B are side, cross-sectional views of two embodiments of the odd-mode resistor circuit 270, 270′ of FIG. 4 through line 6-6. FIG. 7 is an example of a first low-inductance odd-mode resistor circuit 290, 290′, according to one or more embodiments. FIGS. 8A and 8B are side, cross-sectional views of two embodiments of the odd-mode resistor circuit 290, 290′ of FIG. 7 through line 8-8, and FIGS. 9A and 9B are side, cross-sectional views of two embodiments of the odd-mode resistor circuit 290, 290′ of FIG. 7 through line 9-9.

FET 200 may employ a multi-layer circuit configured integrally formed within a semiconductor die 202. As best shown in FIGS. 5A, 5B, 6A, 6B, 8A, 8B, 9A, and 9B, the semiconductor die 202 is defined by a bottom surface 203, a top surface 204, and four sides that extend between the bottom and top surfaces 203, 204 (e.g., including opposite first and second sides 205, 206). The semiconductor die 202 includes a base semiconductor substrate 208 (or “base substrate”) and a build-up structure 212 coupled to a top surface 211 of the base substrate 208. A top surface of the build-up structure 212 corresponds to the top surface 204 of the semiconductor die 202.

The base semiconductor substrate 208 may be formed, for example, from bulk or composite semiconductor materials (e.g., silicon (Si), silicon carbide (SiC), gallium nitride (GaN), gallium arsenide (GaAs), silicon-on-insulator (SoI), GaN-on-insulator (e.g., GaN on Si, GaN on silicon carbide, GaN on sapphire, and so on), or other suitable materials). According to one or more embodiments, a conductive layer 210 is coupled to the bottom surface 209 of the base semiconductor substrate 208, and the conductive layer 210 defines the bottom surface 203 of the semiconductor die 202. The conductive layer 210 corresponds to a ground node for the semiconductor die 202 (i.e., a conductive feature that may be coupled to a system ground).

The build-up structure 212 includes multiple dielectric layers 216, 217, 218, 219 that separate multiple patterned conductive layers 213, 214, 215, along with conductive vias (e.g., vias 258, 259, 291, 292) that electrically connect portions of the conductive layers 213-215. The dielectric layers are formed from one or more dielectric materials, and may include, for example, a passivation layer 216 connected to the top surface 211 of the base semiconductor substrate 208, and multiple additional dielectric layers 217-219 deposited over the passivation layer 216. Although FIGS. 5A, 5B, 6A, 6B, 8A, 8B, 9A, and 9B show four dielectric layers 216-219, in other embodiments, more or fewer dielectric layers may be included in the build-up structure 212.

The conductive layers 213-215 are formed from one or more conductive materials, and patterned portions of the conductive layers 213-215 provide electrical connections between structures and regions at the surface 211 of base substrate 208 (e.g., gate structures and doped drain/source regions) and input and output terminals (e.g., input and output bond pads 252, 262) that are exposed at the top surface of the build-up structure 212. Although FIGS. 5A, 5B, 6A, 6B, 8A, 8B, 9A, and 9B show three conductive layers 213-215, in other embodiments, more or fewer conductive layers may be included in the build-up structure 212. In addition, although various features are illustrated within particular ones of the conductive layers 213-215, such features may be located in different layers than those depicted.

The semiconductor die 202 has several distinct “areas”, where each “area” corresponds to a portion of the die 202 that could be separated from other portions by planes that are perpendicular to the top and bottom surfaces of the die 202. For example, according to one or more embodiments, the semiconductor die 202 has a centrally located active area 229, a gate-side inactive area 250 between the active area 229 and the first side 205 of the die 202 (also referred to as the “gate side 205”), and a drain-side inactive area 260 between the active area 229 and the second side 206 of the die 202 (also referred to as the “drain side 206”). As used herein, “active area” means a portion of the semiconductor die 202 in which active transistor structures and device regions are formed. Conversely, “inactive area” means a portion of the semiconductor die 202 that does not include active transistor structures or device regions.

The active area 229 of die 202 includes a plurality of elongated transistor fingers 230, which extend between the gate-side and drain-side inactive areas 250, 260, and which are arranged in parallel with each other over the width of the die 202. For example, the enlarged portion 298 of FET 200 shown in FIG. 3 shows ten (10) transistor fingers 230 (each surrounded with a dashed box). As indicated in FIG. 2, FET 200 may include more than ten transistor fingers 230. Another embodiment of a FET 200 may include fewer than ten transistor fingers 230.

Each of the transistor fingers 230 essentially includes the same functional transistor structures. More specifically, each transistor finger 230 includes an elongated drain structure 236, an elongated source structure 240, and an elongated gate structure 232 positioned between the elongated drain and source structures 236, 240 of the finger 230. Each drain structure 236 includes a doped elongated drain region in the base semiconductor substrate 208, and an elongated conductive drain contact in the build-up structure 212, which overlies and contacts the elongated drain region. According to one or more embodiments, the conductive drain contacts may be formed from portions of a lowest conductive layer (e.g., layer 213). As used herein, the term “contact” refers to an electrically conductive feature that directly contacts the top surface 211 of the base substrate 208 (although a contact may be recessed below the top surface, as well). According to an embodiment, the drain contacts and (below-described) source contacts may be ohmic contacts.

A proximal end 237 of each drain contact is connected to one of a plurality of conductive drain manifolds 239 in the drain-side inactive area 260, and a distal end 238 of each drain contact is located at or near the boundary of the gate-side inactive area 250. The drain manifolds 239 underlie the segments of the output bond pad 262, and each drain manifold 239 is electrically coupled to a segment of the output bond pad 262 through one or more conductive vias 266. The drain manifolds 239 may be formed, for example, from portions of a conductive layer (e.g., one of conductive layers 213 or 214) of the build-up structure 212. As will be discussed later, non-conductive gaps are present between adjacent drain manifolds 239, and the gaps between the drain manifolds 239 underlie corresponding gaps 264 between adjacent segments of the output bond pad 262.

Each source structure 240 includes a doped elongated source region in the base semiconductor substrate 208, and an elongated conductive source contact in the build-up structure 212, which overlies and contacts the elongated source region. The source region and source contact each may extend the entire length of the transistor finger 230. According to one or more embodiments, the conductive source contacts may be formed from portions of a lowest conductive layer (e.g., layer 213).

Each source structure 240 (and more specifically, each source contact) is electrically coupled to a conductive source through substrate via (TSV) 244. Each source TSV 244 extends from a top surface 211 of the base semiconductor substrate 208 to the conductive layer 210 on the bottom surface 209 of the base semiconductor substrate 208.

Each elongated gate structure 232 includes an elongated conductive gate within the build-up structure 212, which overlies an elongated channel region (not numbered) in the base semiconductor substrate 208. A proximal end 233 of each gate is connected to one of a plurality of conductive gate manifolds 235 in the gate-side inactive area 250, and a distal end 234 of each gate contact is located at or near the boundary of the drain-side inactive area 260. The gate manifolds 235 underlie the segments of the input bond pad 252, and each gate manifold 235 is electrically coupled to a segment of the input bond pad 252 through one or more conductive vias 256. The gate manifolds 235 may be formed, for example, from portions of a conductive layer (e.g., one of conductive layers 213 or 214) of the build-up structure 212. As will be discussed later, non-conductive gaps are present between adjacent gate manifolds 235, and the gaps between the gate manifolds 235 underlie corresponding gaps 254 between adjacent segments of the input bond pad 252.

Each channel region (not numbered) is positioned in the base semiconductor substrate 208 between the drain and source regions of a transistor finger 230. During operation of FET 200, an input signal (e.g., an input RF signal) applied to a gate contact (and more specifically to the gate bond pad 252) varies the conductivity of the channel, resulting in a time-varying current flow between source and drain regions (and thus between the source and drain contacts) of the transistor finger 230.

In the gate-side inactive area 250, FET 200 includes a segmented input bond pad 252 proximate a first side 205 of the die 202. Similarly, in the drain-side inactive area 260, FET 200 includes a segmented output bond pad 262 proximate the second side 206 of the die 202. The segmented input bond pad 252 may be thought of more generally as an input terminal of FET 200, and the segmented output bond pad 262 may be thought of more generally as an output terminal of FET 200. The active area 229 is located between the gate-side and drain-side inactive areas 250, 260 (i.e., between the segmented input and output bond pads 252, 262).

The segmented input bond pad 252 includes a plurality of input bond pad segments 252-1, 252-2, 252-3, 252-4, 252-5, 252-6 (e.g., bond pad segments 152-1 through 152-6, FIG. 1). Each input bond pad segment 252-1 through 252-6 includes a portion of an uppermost conductive layer (e.g., conductive layer 215), which is exposed at the top surface 204 of the semiconductor die 202. Furthermore, each input bond pad segment 252-1 through 252-6 has a geometry that is suitable for attachment of the ends of one or more wirebonds (e.g., connections 146, FIG. 1).

A non-conductive gap 254 (FIG. 3) is present between sets of adjacent input bond pad segments (e.g., between segments 252-1 and 252-2, between segments 252-2 and 252-3, and so on). The proximal ends 233 of gate structures 232 are electrically coupled through the gate manifolds 235 and vias 256 to the input bond pad segments 252-1 through 252-6. According to one or more embodiments, adjacent input bond pad segments (e.g., adjacent segments 252-1 and 252-2 or adjacent segments 252-2 and 252-3) are electrically coupled to the proximal ends 233 of gate structures 232 in different (adjacent) transistor fingers 230. For example, bond pad segment 252-1 is electrically coupled to a first gate of a first transistor finger 230, and bond pad segment 252-2 is electrically coupled to a second gate of a second transistor finger 230.

Similarly, the segmented output bond pad 262 includes a plurality of output bond pad segments 262-1, 262-2, 262-3 (e.g., bond pad segments 162-1 through 162-3, FIG. 1). Each output bond pad segment 262-1 through 262-3 includes a portion of an uppermost conductive layer (e.g., conductive layer 215), which is exposed at the top surface 204 of the semiconductor die 202. Furthermore, each output bond pad segment 262-1 through 262-3 has a geometry that is suitable for attachment of the ends of one or more wirebonds (e.g., connections 147, FIG. 1).

A non-conductive gap 264 (FIG. 3) is present between sets of adjacent output bond pad segments (e.g., between segments 262-1 and 262-2, between segments 262-2 and 262-3). The proximal ends 237 of drain structures 236 are electrically coupled through the drain manifolds 239 and vias 266 to the output bond pad segments 262-1 through 262-3. According to one or more embodiments, adjacent output bond pad segments (e.g., adjacent segments 262-1 and 262-2 or adjacent segments 262-2 and 262-3) are electrically coupled to the proximal ends 237 of drain structures 236 in different (adjacent) transistor fingers 230. For example, bond pad segment 262-1 is electrically coupled to a first drain structure of a first transistor finger 230, and bond pad segment 262-2 is electrically coupled to a second drain structure of a second transistor finger 230.

According to one or more embodiments, first odd-mode resistor circuits 270, 270′ (or “odd-mode oscillation stabilization circuits”) are electrically coupled between each pair of adjacent input bond pad segments (e.g., adjacent segments 252-1 and 252-2 or adjacent segments 252-2 and 252-3). The first odd-mode resistor circuits 270, 270′ may be located within the gate-side inactive area 250. According to one or more embodiments, each first odd-mode resistor circuit 270, 270′ is more specifically positioned within the build-up structure 212 in the gate-side inactive area 250 underneath or within the non-conductive gap 254 between adjacent input bond pad segments. According to one or more alternate embodiments, all or a portion of each first odd-mode resistor circuit 270, 270′ may be positioned below an input bond pad segment 252-1 through 252-6, rather than being aligned with a non-conductive gap 254.

Similarly, according to one or more further embodiments, second odd-mode resistor circuits 290, 290′ are electrically coupled between each pair of adjacent output bond pad segments (e.g., adjacent segments 262-1 and 262-2 or adjacent segments 262-2 and 262-3). The second odd-mode resistor circuits 290, 290′ may be located within the drain-side inactive area 260. According to one or more embodiments, each second odd-mode resistor circuit 290, 290′ is more specifically positioned within the build-up structure 212 in the drain-side inactive area 260 underneath or within the non-conductive gap 264 between adjacent output bond pad segments. According to one or more alternate embodiments, all or a portion of each second odd-mode resistor circuit 290, 290′ may be positioned below an output bond pad segment 262-1 through 262-3, rather than being aligned with a non-conductive gap 264.

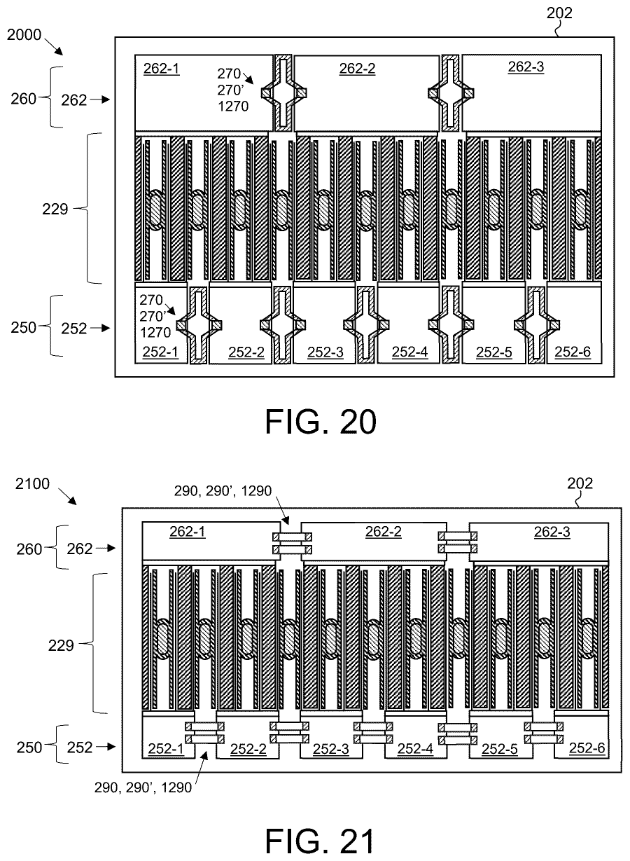

According to one or more embodiments, the first and second odd-mode resistor circuits 270, 270′, 290, 290′ function to dissipate energy for any signals traveling laterally within the FET 200 (i.e., in a horizontal direction in FIGS. 2, 3), while having little or no impact on the intended signal for amplification. As will be described in more detail below, the first and second odd-mode resistor circuits 270, 270′, 290, 290′ may have any of a variety of configurations, and two such configurations are shown in FIGS. 2 and 3. More specifically, as will be described below in detail in conjunction with FIGS. 4, 5A, 5B, 6A, and 6B, the first odd-mode-resistor circuits 270, 270′ each may include first and second “mutual-inductance resistors” 272, 272′ (FIG. 4) electrically coupled in parallel between adjacent input bond bad segments. Similarly, as will be described below in detail in conjunction with FIGS. 7, 8A, 8B, 9A, and 9B, the second odd-mode-resistor circuits 290, 290′ each may include first and second “parallel-coupled resistors” 294, 294′ (FIG. 7) electrically coupled in parallel between adjacent output bond bad segments. As used herein, the term “parallel-coupled” means “electrically coupled in parallel.” This represents one particular combination of types of odd-mode resistor circuits that may be included in a particular embodiment of a FET. As will be discussed later in conjunction with FIGS. 20-22, different combinations of types of odd-mode resistor circuits may be included in other embodiments of FETs.

Referring first to FIGS. 4, 5A, 5B, 6A, and 6B, a top view and side, cross-sectional views of various embodiments of the first odd-mode-resistor circuits 270, 270′ (FIGS. 2, 3) are illustrated. As mentioned above, a first odd-mode resistor circuit 270, 270′ may include first and second mutual-inductance resistors 272, 272′ electrically coupled in parallel between adjacent bond pad segments (e.g., between input bond pad segments 252-1, 252-2), which are indicated with dashed-dotted boxes in FIG. 4. In addition, the first odd-mode resistor circuit 270, 270′ may include conductive features (e.g., conductive vias 258, 259) that electrically couple the mutual-inductance resistors 272, 272′ to the adjacent input bond pad segments 252-1, 252-2.

Each first and second mutual-inductance resistor 272, 272′ includes a length of conductive and resistive material (referred to herein as “resistor material”) that extends between and electrically connects to a first terminal 273, 273′ (or first end) of the resistor 272, 272′ and a second terminal 274, 274′ (or second end) of the resistor 272, 272′. As indicated above and shown in FIGS. 4, 5A, 5B, 6A, and 6B, the first terminal 273, 273′ may be electrically coupled to a first bond pad segment 252-1 through one or more first conductive vias 258, and the second terminal 274, 274′ may be electrically coupled to a second bond pad segment 252-2 through one or more second conductive vias 259.

In the embodiments of FIGS. 4, 5A, 5B, 6A, and 6B, the length of resistor material forming each resistor 272, 272′ may be a patterned portion of a conductive layer that is deposited and patterned during the back end of line (BEOL) process of fabricating the FET 200. In some embodiments, the resistors 272, 272′ may be formed from the same material as one of the conductive layers 213, 214. Alternatively, in other embodiments, the resistors 272, 272′ may be formed from layers of other resistor materials that are separately deposited and patterned during the BEOL process. For example, in FIGS. 5A and 6A, resistors 272, 272′ are formed from patterned portions of a separately-deposited conductive material 513 that is directly above passivation layer 216, and in FIGS. 5B and 6B, resistors 272, 272′ are formed from patterned portions of a separately-deposited conductive material 513′ that overlies dielectric layer 217. Alternatively, as will be described later in conjunction with FIGS. 12-15, the resistors may be formed on the top surface 204 of the semiconductor die 202.

Either way, resistors 272, 272′ are desirably formed from a conductive material that has a relatively-high resistivity (e.g., a material characterized by a resistivity of 0.40 microohms meters (μΩ·m) or more, or by a resistivity of 1.0 μΩ·m or more), when compared with the resistivity of other metals (e.g., copper, aluminum), which may be used to form interconnects and vias in the BEOL process. For example, resistors 272, 272′ may be formed from one or more materials selected from Nichrome (Ni, Fe, Cr alloy), titanium tungsten (TiW), titanium tungsten nitride (TiWN), a cobalt alloy, or other suitable materials. In some embodiments, resistors 272, 272′ may be formed from resistive semiconductor material (e.g., doped silicon regions and/or active and isolated regions of the base semiconductor substrate 208). Nichrome and TiW, for example, may have a resistivity equal to or greater than 012 μΩ·m, and thus these materials may be particularly suitable for forming resistors 272, 272′.

Referring to FIG. 4, the first mutual-inductance resistor 272 includes a first mutual-inductance structure 275 that includes a first elongated resistor segment 276 and a second elongated resistor segment 277, which are arranged next to each other and physically oriented in parallel across a non-conductive gap 284. First ends of the first and second resistor segments 276, 277 are electrically coupled to the first and second terminals 273, 274, respectively, and thus are electrically coupled to the conductive vias 258, 259 (and the first and second input bond pad segments 252-1, 252-2). Second ends of the first and second resistor segments 276, 277 are electrically coupled together through a transverse resistor segment 278. Accordingly, the first and second resistor segments 276, 277 are electrically coupled in series between the first and second terminals 273, 274.

During operation of FET 200, the first resistor segment 276 is configured to carry current in a first direction (indicated by arrow 261), and the second resistor segment 277 is configured to carry current in a second direction (indicated by arrow 263), which is opposite the first direction. Accordingly, the first mutual-inductance resistor 272 is characterized by a negative mutual coupling during operation of FET 200. This negative mutual coupling essentially functions to reduce the effective inductance (parasitic inductance) of the first mutual-inductance resistor 272, which in turn may improve the odd-mode stability of the FET 200.

Optionally, the first ends of the resistor segments 276, 277 are coupled to the first and second terminals 273, 274 through angled resistor segments 279, which may be used to transition between the distance (pitch) between the vias 258, 259 and a desired gap width 285. In other embodiments (see, e.g., FIG. 18), the angled resistor segments 279 are not included.

Similarly, the second mutual-inductance resistor 272′ includes a second mutual-inductance structure 275′ that includes a third elongated resistor segment 276′ and a fourth elongated resistor segment 277′, which are arranged next to each other and physically oriented in parallel across a non-conductive gap 284′. First ends of the third and fourth resistor segments 276′, 277′ are electrically coupled to the first and second terminals 273′, 274′, respectively, and thus are electrically coupled to the conductive vias 258, 259 (and the first and second input bond pad segments 252-1, 252-2). The third and fourth resistor segments 276′, 277′ are electrically coupled in series between the first and second terminals 273′, 274′.

Again, during operation of FET 200, the third resistor segment 276′ is configured to carry current in a first direction, and the fourth resistor segment 277′ is configured to carry current in a second direction, which is opposite the first direction. Accordingly, the second mutual-inductance resistor 272′ is characterized by a negative mutual coupling during operation of FET 200. This negative mutual coupling essentially functions to reduce the effective inductance (parasitic inductance) of the second mutual-inductance resistor 272′, which again may improve the odd-mode stability of the FET 200.

Optionally, the first ends of the resistor segments 276′, 277′ are coupled to the first and second terminals 273′, 274′ through angled resistor segments 279′, which may be used to transition between the distance (pitch) between the vias 258, 259 and a desired gap width 285. Again, in other embodiments (see, e.g., FIG. 18), the angled resistor segments 279′ are not included. Second ends of the third and fourth resistor segments 276′, 277′ are electrically coupled together through a transverse resistor segment 278′.

According to an embodiment, the first, second, third, and fourth resistor segments 276, 277, 276′, 277′, angled resistor segments 279, 279′ (if included), and transverse resistor segments 278, 278′ are integrally formed from a single layer 513, 513′ of resistor material. In other embodiments, the first, second, third, and fourth resistor segments 276, 277, 276′, 277′, angled resistor segments 279, 279′ (if included), and/or transverse resistor segments 278, 278′ may be formed from portions of different layers of resistor material. Further, according to one or more embodiments, the first and second mutual-inductance resistors 272, 272′ are mirror images of each other, and accordingly, the first odd-mode resistor circuit 270, 270′ is symmetrical about a line of symmetry 271 that is parallel with the first and second sides 205, 206 of the semiconductor die 202. For example, the first mutual-inductance resistor 272 (and thus the first and second resistor segments 276, 277) may extend from the first and second terminals 273, 274 towards the first side 205 of the semiconductor die 202, and the second mutual-inductance resistor 272′ (and thus the third and fourth resistor segments 276′, 277′) may extend from the first and second terminals 273′, 274′ towards the second side 206 of the semiconductor die 202.

The first and second mutual-inductance resistors 272, 272′ are characterized by various dimensions. For example, resistors 272, 272′ are characterized by a resistor length dimension 280 (perpendicular to the first and second sides 205, 206 of the die 202), which is half of the total overall length of the first odd-mode resistor circuit 270, 270′. According to one or more embodiments, the resistor length dimension 280 is in a range of about 30 microns to about 100 microns, although dimension 280 may be smaller or larger, as well. Resistors 272, 272′ are further characterized by a resistor width dimension 281 (parallel with the first and second sides 205, 206 of the die 202), which may be roughly equal to the lateral distance between the first and second terminals 273, 274 (or 273′, 274′). According to one or more embodiments, the resistor width dimension 281 is in a range of about 15 microns to about 30 microns, although dimension 281 may be smaller or larger, as well.

The first and second mutual-inductance structures 275, 275′ are further characterized by width and length dimensions 282, 283. The length dimensions 283 correspond to the lengths of the first, second, third, and fourth resistor segments 276, 277, 276′, 277′. According to one or more embodiments, the length dimension 282 is in a range of about 6 microns to about 10 microns, and the width dimension 283 is in a range of about 24 microns to about 94 microns, although dimensions 282, 283 may be smaller or larger, as well.

The first and second mutual-inductance structures 275, 275′ also are characterized by a gap width dimension 285, which represents the distance between the interior edges of the first and second resistor segments 276, 277 or the third and fourth resistor segments 276′, 277′. It should be noted here that the gap width dimension 285 is established to produce a desired level of the above-described, negative mutual coupling between the first and second resistor segments 276, 277 and between the third and fourth resistor segments 276′, 277′ during operation of FET 200. According to one or more embodiments, the gap width dimension 285 is in a range of about 2 microns to about 4 microns, although dimension 285 may be smaller or larger, as well. Generally, a larger length dimension 283 coupled with a smaller gap width dimension 285 results in stronger negative mutual coupling between signals carried through the mutual-inductance structures 275, 275′ (and thus a lower effective inductance). Conversely, a shorter length dimension 283 coupled with a wider gap width dimension 285 results in weaker negative mutual coupling between signals carried through the mutual-inductance structures 275, 275′ (and thus a relatively higher effective inductance). According to one or more embodiments, the gap width dimension 285 should be sufficiently small so that the odd-mode resistor circuits 270, 270′ are characterized by a significant negative mutual inductance during operation (e.g., a negative mutual inductance that results in at least a 50% decrease in the overall inductance of each of the first and second mutual inductance structures 275, 275′).

The first and second mutual-inductance resistors 272, 272′ also are characterized by an electrical length (e.g., path length) between the first and second terminals 273, 274 (or 273′ to 274′). The resistor value of each of resistors 272, 272′ is a function of its electrical length, the cross-sectional area of each resistor segment (within a plane that is perpendicular to the electrical length), and the resistivity of the resistor material. According to one or more embodiments, the total resistance value for the first and second mutual-inductance resistors 272, 272′ is approximately half of the resistor value for each resistor 272, 272′. According to one or more embodiments, the resistor value of each of the first and second mutual-inductance resistors 272, 272′ is in a range of about 4 ohms to about 12 ohms, and the total resistance value for the first and second mutual-inductance resistors 272, 272′ is in a range of about 2 ohms to about 6 ohms. In other embodiments, the resistor values (or total resistance value) may be smaller or larger.

The total resistance value of each of the first odd-mode resistor circuits 270, 270′ is selected to ensure that the circuits 270, 270′ effectively dampen odd-mode loop currents within FET 200. As mentioned previously, the parasitic inductance of any odd-mode resistor circuit negatively affects the odd-mode stability of a FET. Accordingly, there is a desire to provide an odd-mode resistor circuit with sufficiently high resistance to effectively dampen the odd-mode loop currents while having a sufficiently low parasitic inductance to ensure adequate odd-mode stability. The first odd-mode resistor circuits 270, 270′ achieve this balance by providing multiple paths of resistance through each of the first odd-mode resistor circuits 270, 270′. An odd-mode resistor circuit 270, 270′ with only a single mutual-inductance resistor 272 or 272′ may result in a reduction of parasitic inductance to about half of what the parasitic inductance would be if a single conventional resistor (with an equivalent resistance) were used. By providing each odd-mode resistor circuit 270, 270′ with two mutual-inductance resistors 272, 272′ that are electrically coupled in parallel, the parasitic inductance of each odd-mode resistor circuit 270, 270′ may be about one quarter of what the parasitic inductance would be if a single conventional resistor (with an equivalent resistance) were used. Utilizing odd-mode resistor circuits 270, 270′ with significantly reduced parasitic inductance has an effect on the odd-mode stability of FET 200.

Referring next to FIGS. 7, 8A, 8B, 9A, and 9B, a top view and side, cross-sectional views of various embodiments of the second odd-mode resistor circuits 290, 290′ (FIGS. 2, 3) are illustrated. As mentioned above, a second odd-mode resistor circuit 290, 290′ may include first and second parallel-coupled resistors 294, 294′ electrically coupled in parallel between adjacent bond pad segments (e.g., between output bond pad segments 262-1, 262-2), which are indicated with dashed-dotted boxes in FIG. 7. In addition, the second odd-mode resistor circuit 290, 290′ may include conductive features (e.g., conductive vias 288, 288′, 289, 289′) that electrically couple the parallel-coupled resistors 294, 294′ to the adjacent output bond pad segments 262-1, 262-2.

Each first and second parallel-coupled resistor 294, 294′ includes a length of resistor material that extends between and electrically connects to a first terminal 291, 291′ (or first end) of the resistor 294, 294′ and a second terminal 292, 292′ (or second end) of the resistor 294, 294′. As indicated above and shown in FIGS. 7, 8A, 8B, 9A, and 9B, the first terminals 291, 291′ may be electrically coupled to a first bond pad segment 262-1 through one or more first conductive vias 288, 288′, and the second terminals 292, 292′ may be electrically coupled to a second bond pad segment 262-2 through one or more second conductive vias 289, 289′.

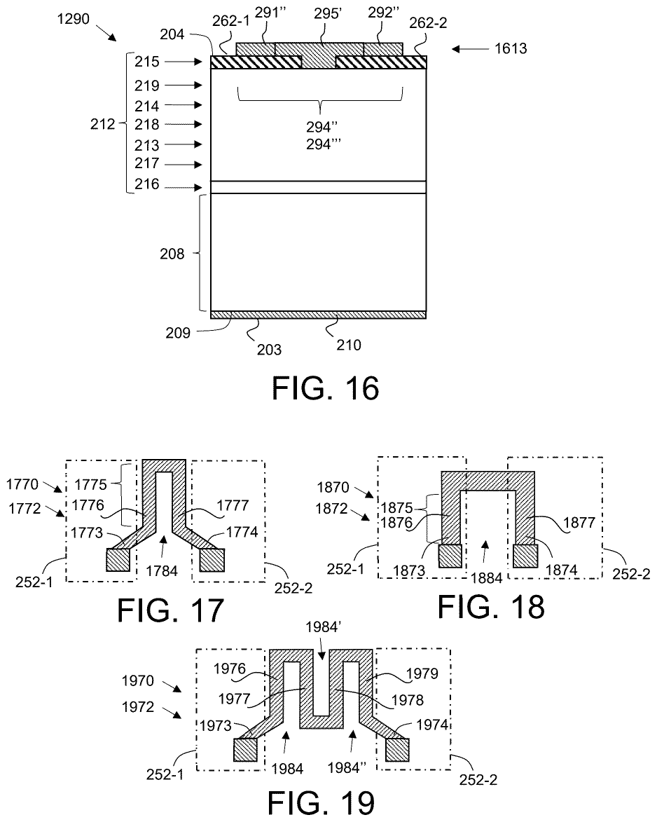

In the embodiments of FIGS. 7, 8A, 8B, 9A, and 9B, the length of resistor material forming each resistor 294, 294′ may be a patterned portion of a conductive layer that is deposited and patterned during the BEOL process of fabricating the FET 200. In some embodiments, the resistors 294, 294′ may be formed from the same material as one of the conductive layers 213, 214. Alternatively, in other embodiments, the resistors 294, 294′ may be formed from layers of other resistor materials that are separately deposited and patterned during the BEOL process. For example, in FIGS. 8A and 9A, resistors 294, 294′ are formed from patterned portions of a separately-deposited conductive material 813 that is directly above passivation layer 216, and in FIGS. 8B and 9B, resistors 294, 294′ are formed from patterned portions of a separately-deposited conductive material 813′ that overlies dielectric layer 217. Alternatively, as will be described later in conjunction with FIG. 16, the resistors may be formed on the top surface 204 of the semiconductor die 202.

Either way, resistors 294, 294′ are desirably formed from a conductive material that has a relatively-high resistivity (e.g., a material characterized by a resistivity of 0.40μΩ·m or more, or by a resistivity of 1.0μΩ·m or more), when compared with the resistivity of other metals (e.g., copper, aluminum), which may be used to form interconnects and vias in the BEOL process. For example, resistors 294, 294′ may be formed from one or more materials selected from Nichrome, TiW, TiWN, a cobalt alloy, semiconductor material, or other suitable materials.

Referring to FIG. 7, the first parallel-coupled resistor 294 includes a first elongated resistor segment (also referred to as a “resistor segment”) (not separately numbered), which extends between and electrically connects to first and second terminals 291, 292. Similarly, the second parallel-coupled resistor 294′ includes a second elongated resistor segment (not separately numbered), which extends between and electrically connects to first and second terminals 291′, 292′. The first and second parallel-coupled resistors 294, 294′ (and particularly, the first and second elongated segments of resistor materials) are arranged next to each other, are electrically-coupled in parallel, and also are physically oriented in parallel across a non-conductive gap 293.

For the first resistor 294, a first end of the first elongated resistor segment is electrically coupled to the first terminal 291, and a second end of the first elongated resistor segment is electrically coupled to the second terminal 292. Thus, the first and second ends of the first resistor 294 are electrically coupled to the conductive vias 288, 289 (and the first and second output bond pad segments 262-1, 262-2). Similarly, for the second resistor 294′, a first end of the second elongated resistor segment is electrically coupled to the first terminal 291′, and a second end of the second elongated resistor segment is electrically coupled to the second terminal 292′. Thus, the first and second ends of the second resistor 294′ are electrically coupled to the conductive vias 288′, 289′ (and the first and second output bond pad segments 262-1, 262-2).

During operation of FET 200, the first and second parallel-coupled resistors 294, 294′ are configured to carry current in the same direction. However, by using two parallel-coupled resistors 294, 294′ to achieve the desired effective resistance, the overall parasitic inductance of the odd-mode resistor circuit 290, 290′ is about half of what it would be if a single odd-mode resistor with the same effective resistance were used. Accordingly, including two parallel-coupled resistors 294, 294′ essentially functions to reduce the effective inductance (parasitic inductance) of the odd-mode resistor circuit 290, 290′, which in turn may improve the odd-mode stability of the FET 200.

According to an embodiment, the first and second resistors 294, 294′ are formed from a single layer 813, 813′ of resistor material. In other embodiments, the first and second resistors 294, 294′ may be formed from portions of different layers of resistor material. Further, according to one or more embodiments, the first and second parallel-coupled resistors 294, 294′ are substantially identical to each other.

The first and second parallel-coupled resistors 294, 294′ are characterized by various dimensions. For example, resistors 294, 294′ are characterized by a resistor length dimension 296 (parallel with the first and second sides 205, 206 of the die 202), which may be roughly equal to the lateral distance between the first and second terminals 291, 292 (or 291′, 292′). According to one or more embodiments, the resistor length dimension 296 is in a range of about 60 microns to about 80 microns, although dimension 296 may be smaller or larger, as well. Resistors 294, 294′ are further characterized by a resistor width dimension 297 (perpendicular to the first and second sides 205, 206 of the die 202). According to one or more embodiments, the resistor width dimension 297 is in a range of about 10 microns to about 60 microns, although dimension 297 may be smaller or larger, as well.

Resistors 294, 294′ also are characterized by an electrical length (e.g., path length) between the first and second terminals 291 to 292 (or 291′ to 292′). The resistor value of each of the first and second parallel-coupled resistors 294, 294′ is a function of its electrical length, the cross-sectional area of each resistor segment (within a plane that is perpendicular to the electrical length), and the resistivity of the resistor material. According to an embodiment, the resistor segments of the first and second parallel-coupled resistors 294, 295 may have substantially the same dimensions and electrical properties (e.g., resistor value) as each other. In other words, resistors 294, 295 essentially may be copies of each other. Accordingly, the total effective resistance value for the first and second parallel-coupled resistors 294, 294′ is approximately half of the resistor value for each resistor 294, 294′. According to one or more embodiments, the resistor value of each of the first and second parallel-coupled resistors 294, 294′ is in a range of about 14 ohms to about 30 ohms, and the total resistance value for the first and second parallel-coupled resistors 294, 294′ is in a range of about 7 ohms to about 15 ohms. In other embodiments, the resistor values (or total resistance value) may be smaller or larger.

As discussed above, the parallel-coupled resistors 294, 294′ include resistor segments that are separated across a non-conductive gap 293, along with first and second terminals 291, 291′, 292, 292′ at the ends of each segment. According to one or more alternate embodiments, rather than utilizing two separated segments of resistor material, a low-inductance odd-mode resistor may be formed with a single mass of resistor material with terminals roughly at each corner of the mass of resistor material.

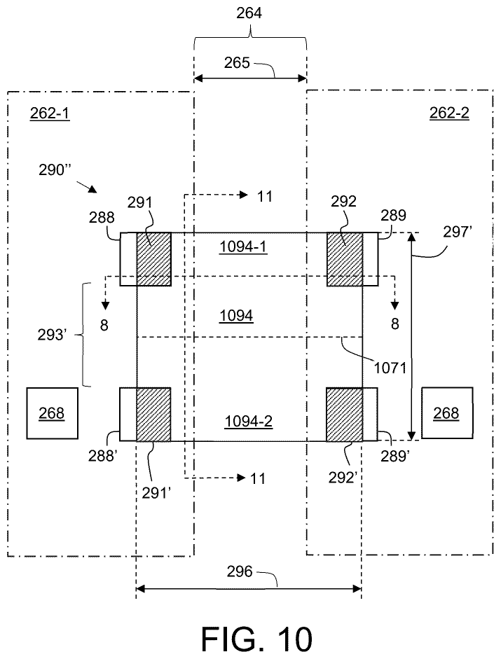

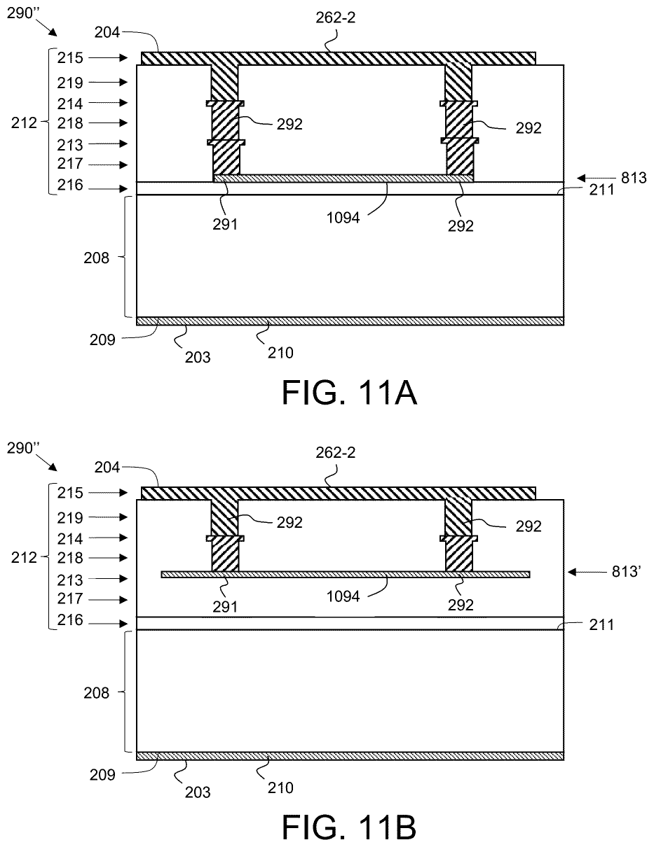

For example, FIG. 10 is an example of yet another embodiment of a low-inductance odd-mode resistor circuit 290″. FIG. 10 should be viewed simultaneously with FIGS. 11A and 11B, which are cross-sectional side views of two embodiments of the resistor circuit 290″ of FIG. 10 through line 11-11. It may be noted here that the cross-sectional views of embodiments of odd-mode resistor circuit 290″ (FIG. 10) through line 8-8 may be substantially similar to the cross-sectional views of odd-mode resistor circuits 290, 290′ (FIG. 7) through line 8-8 (FIGS. 8A, 8B). For conciseness, separate drawings are not included to depict cross-sectional views of odd-mode resistor circuit 290″ through line 8-8.

Referring next to FIGS. 10, 11A, and 11B, a top view and side, cross-sectional views of a third odd-mode resistor circuit 290″ (FIG. 10) is shown. The third odd-mode resistor circuit 290″ may include a 2^{N}-terminal resistor 1094 (N>1), which is electrically coupled between adjacent bond pad segments (e.g., between output bond pad segments 262-1, 262-2, indicated with dashed-dotted boxes in FIG. 10). In the embodiment of FIG. 10, for example, the third odd-mode resistor circuit 290″ includes a 4-terminal resistor 1094 (i.e., N=2). In other embodiments, the third odd-mode resistor circuit 290″ may include a resistor 1094 that has 4, 8, or more terminals. In addition, the third odd-mode resistor circuit 290″ may include conductive features (e.g., conductive vias 288, 288′, 289, 289′) that electrically couple the 2N-terminal resistor 1094 to the adjacent output bond pad segments 262-1, 262-2.

The 2^{N}-terminal resistor 1094 of odd-mode resistor circuit 290″ includes a mass of resistor material that extends between and electrically connects to first, second, third, and fourth terminals 291, 291′, 292, 292′. For example, the mass of resistor material may have a substantially rectangular, sheet-like form factor, where the four terminals 291, 291′, 292, 292′ each are positioned proximate to (and connected to) a different corner of the sheet. The mass of resistor material may be considered to have first and second resistor segments 1094-1 and 1094-2, which are integrally-formed together, arranged next to each other, and physically oriented in parallel. For purposes of clarity, line 1071 delineates the first and second resistor segments 1094-1, 1094-2.

As indicated above and shown in FIGS. 10, 11A, and 11B, the first and second terminals 291, 291′ may be electrically coupled to a first bond pad segment 262-1 through one or more first conductive vias 288, 288′, and the third and fourth terminals 292, 292′ may be electrically coupled to a second bond pad segment 262-2 through one or more second conductive vias 289, 289′. The first and second terminals 291, 291′ are separated by a gap 293′ that may have a width in a range of about 1 micron to about 100 microns, although the gap 293′ may be smaller or larger, as well. Further, the first and third terminals 291, 292 and the second and fourth terminals 291′, 292′ each are separated by a gap (not numbered) that is at least as wide as the gap 264 between bond pad segments 262-1, 262-2.

In the embodiments of FIGS. 10, 11A, and 11B, the mass of resistor material forming resistor 1094 may be a patterned portion of a conductive layer that is deposited and patterned during the BEOL process of fabricating the FET 200. In some embodiments, the resistor 1094 may be formed from a patterned portion of the same material as one of the conductive layers 213, 214. Alternatively, in other embodiments, the resistor 1094 may be formed from layers of other resistor materials that are separately deposited and patterned during the BEOL process. For example, in FIGS. 8A and 11A, the resistor material of resistor 1094 is formed from a patterned portion of a separately-deposited conductive material 813 that is directly above passivation layer 216, and in FIGS. 8B and 11B, the resistor material of resistor 1094 is formed from a patterned portion of a separately-deposited conductive material 813′ that overlies dielectric layer 217. Alternatively, the resistor material of resistor 1094 may be formed on the top surface 204 of the semiconductor die 202.

Either way, resistor 1094 is desirably formed from a conductive resistor material that has a relatively-high resistivity (e.g., a material characterized by a resistivity of 0.40 Ω·m or more, or by a resistivity of 1.0μΩ·m or more), when compared with the resistivity of other metals (e.g., copper, aluminum), which may be used to form interconnects and vias in the BEOL process. For example, resistor 1094 may be formed from one or more materials selected from Nichrome, TiW, TiWN, a cobalt alloy, semiconductor material, or other suitable materials.

During operation of FET 200, the resistor 1094 is configured to carry current between terminals 291, 291′ and terminals 292, 292′. By utilizing a 2^{N}-terminal odd-mode resistor circuit 290″ (N>1), according to one or more embodiments, with multiple terminals coupled to each of the segmented bond pads 262-1, 262-2, the parallelized parasitic inductance of the odd-mode resistor circuit 290″ is significantly lower than it would be for two-terminal, odd-mode resistor having a similarly-resistive mass of material between its two terminals. Accordingly, including 2^{N} (N>1) terminals to electrically connect the resistor 1094 to the bond pad segments 262-1, 262-2 essentially results in significantly-reduced parasitic inductance of the odd-mode resistor circuit 290″. This, in turn, may significantly improve the odd-mode stability of the FET 200.

Resistor 1094 is characterized by various dimensions. For example, resistor 1094 is characterized by a resistor length dimension 296 (parallel with the first and second sides 205, 206 of the die 202), which may be roughly equal to the lateral distance between the first and second terminals 291, 292 (or 291′, 292′). According to one or more embodiments, the resistor length dimension 296 is in a range of about 60 microns to about 80 microns, although dimension 296 may be smaller or larger, as well. The resistor 1094 is further characterized by a resistor width dimension 297′ (perpendicular to the first and second sides 205, 206 of the die 202). According to one or more embodiments, the resistor width dimension 297′ is in a range of about 20 microns to about 40 microns, although dimension 297′ may be smaller or larger, as well.

Resistor 1094 also is characterized by an electrical length (e.g., path length) between the first terminals 291, 291′ and the second terminals 292, 292′. The resistor value of resistor 1094 is a function of its electrical length, its cross-sectional area (within a plane that is perpendicular to the electrical length), and the resistivity of the resistor material. According to an embodiment, the total resistance value for the resistor 1094 between the first terminals 291, 291′ and the second terminals 292, 292′ is in a range of about 7 ohms to about 14 ohms. In other embodiments, the total resistance value may be smaller or larger.

In the above-described embodiments, various odd-mode resistor circuits 270, 270′, 290, 290′, 290″ include odd-mode resistors that are formed below the top surface 204 of a FET 200. As shown in FIGS. 12-16, in various alternate embodiments, a FET 1200 may include odd-mode resistor circuits 1270, 1290 that include odd-mode resistors that are formed at or on the top surface 204 of a FET 1200.

For example, reference is now made to FIGS. 12-16, which show various top, enlarged, and side cross-sectional views of various embodiments of a FET 1200, which includes odd-mode resistor circuits 1270, 1290 with odd-mode resistors that are formed at or on the top surface 204 of the FET 1200. For enhanced understanding, FIGS. 12-16 should be viewed simultaneously, and the below description of FET 1200 will refer to each of these figures in describing FET 1200.

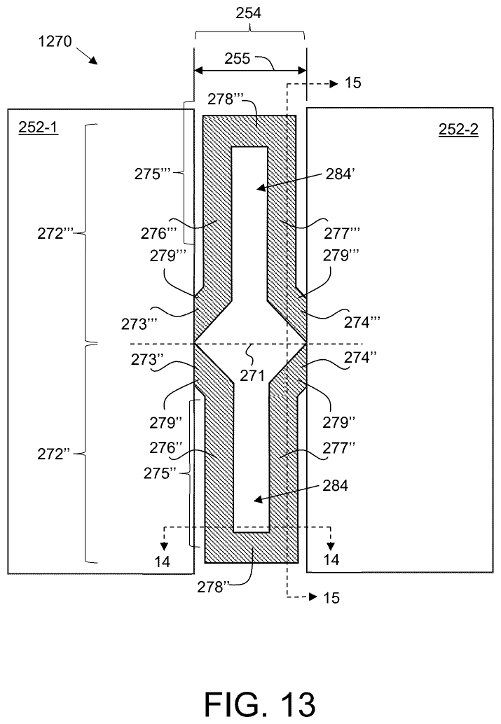

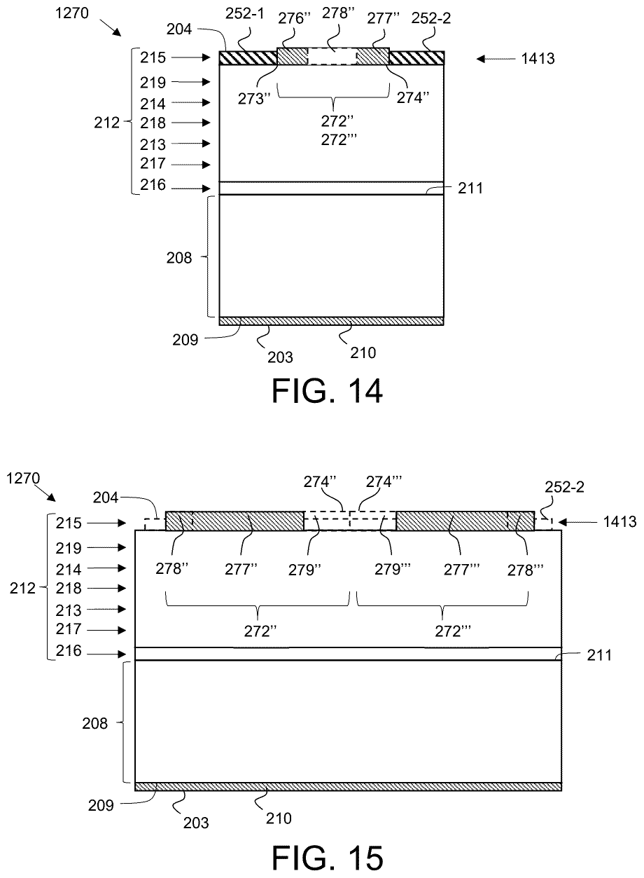

Specifically, FIG. 12 is a top view of an enlarged portion of a FET 1200 with segmented gate and drain bond pads 252, 262, and fourth and fifth embodiments of low-inductance odd-mode resistor circuits 1270, 1290. FIG. 13 is an enlarged view of an example of the fourth low-inductance odd-mode resistor circuit 1270, according to one or more embodiments. FIG. 14 is a side, cross-sectional view of the fourth odd-mode resistor circuit 1270 of FIG. 13 through line 14-14, and FIG. 15 is a side, cross-sectional view of the fourth odd-mode resistor circuit 1270 of FIG. 13 through line 15-15. FIG. 16 is a side, cross-sectional view of the fifth odd-mode resistor circuit 1290 of FIG. 12 through line 16-16.

FET 1200 has many features that are identical or substantially similar to features discussed above with reference to the various embodiments of FET 200 (FIGS. 2, 3). For conciseness, the identical or substantially similar features between FETs 200 and 1200 are not repeated here. Instead, the identical of substantially similar features are indicated with identical reference numbers between the embodiments of FIGS. 2, 3 and the embodiments of FIGS. 12-16. All of the details described above for features in FIGS. 2 and 3 that have the same reference numbers as features in FIGS. 12-16 are incorporated into this description of FIGS. 12-16.

As a brief summary, FET 1200 may employ a multi-layer circuit configured integrally formed within a semiconductor die 202. The semiconductor die 202 includes a base semiconductor substrate 208 and a build-up structure 212 coupled to a top surface 211 of the base substrate 208. The base semiconductor substrate 208 may be formed, for example, from bulk or composite semiconductor materials (e.g., Si, SiC, GaN, GaAs, SoI, GaN-on-insulator, or other suitable materials). A conductive layer 210 is coupled to a bottom surface 209 of the base semiconductor substrate 208.

The semiconductor die 202 has a centrally located active area 229, a gate-side inactive area 250 between the active area 229 and the first side 205 of the die 202, and a drain-side inactive area 260 between the active area 229 and the second side 206 of the die 202. The active area 229 of die 202 includes a plurality of elongated transistor fingers 230, which extend between the gate-side and drain-side inactive areas 250, 260, and which are arranged in parallel with each other over the width of the die 202. Details of the transistor fingers 230 described above in conjunction with FIGS. 2 and 3 are incorporated here.

In the gate-side inactive area 250, FET 1200 includes a segmented input bond pad 252 proximate a first side 205 of the die 202. Similarly, in the drain-side inactive area 260, FET 1200 includes a segmented output bond pad 262 proximate the second side 206 of the die 202. The segmented input bond pad 252 includes a plurality of input bond pad segments 252-1, 252-2, 252-3, 252-4, 252-5, 252-6, and a non-conductive gap 254 is present between sets of adjacent input bond pad segments. Similarly, the segmented output bond pad 262 includes a plurality of output bond pad segments 262-1, 262-2, 262-3, and a non-conductive gap 264 is present between sets of adjacent output bond pad segments.

According to one or more embodiments, fourth odd-mode resistor circuits 1270 are electrically coupled between each pair of adjacent input bond pad segments (e.g., adjacent segments 252-1 and 252-2 or adjacent segments 252-2 and 252-3). The fourth odd-mode resistor circuits 1270 may be located within the gate-side inactive area 250. According to one or more embodiments, each fourth odd-mode resistor circuit 1270 is more specifically positioned within the build-up structure 212 in the gate-side inactive area 250 and within the non-conductive gap 254 between adjacent input bond pad segments.

Similarly, according to one or more further embodiments, fifth odd-mode resistor circuits 1290 are electrically coupled between each pair of adjacent output bond pad segments (e.g., adjacent segments 262-1 and 262-2 or adjacent segments 262-2 and 262-3). The fifth odd-mode resistor circuits 1290 may be located within the drain-side inactive area 260. According to one or more embodiments, each fifth odd-mode resistor circuit 1290 is more specifically positioned within the build-up structure 212 in the drain-side inactive area 260 within the non-conductive gap 264 between adjacent output bond pad segments.

According to one or more embodiments, the fourth and fifth odd-mode resistor circuits 1270, 1290 function to dissipate energy for any signals traveling laterally within the FET 1200 (i.e., in a horizontal direction in FIG. 12), while having little or no impact on the intended signal for amplification. As will be described in more detail below in conjunction with FIGS. 13-15, the fourth odd-mode-resistor circuits 1270 each may include first and second mutual-inductance resistors 272″, 272″′ (FIG. 13) located on or at the top surface 204 of the FET 1200, and which are electrically coupled in parallel between adjacent input bond bad segments. Similarly, as will be described below in detail in conjunction with FIG. 16, the fifth odd-mode-resistor circuits 1290 each may include first and second parallel-coupled resistors 294″, 294″′ (FIG. 12) located on or at the top surface 204 of the FET 1200, and which are electrically coupled in parallel between adjacent output bond bad segments.

Referring first to FIGS. 13-15, a top view and side, cross-sectional views of various embodiments of the fourth odd-mode-resistor circuits 1270 (FIG. 12) are illustrated. As mentioned above, similar to the above-described first odd-mode resistor circuits 270, 270′ (FIGS. 4, 5A, 5B, 6A, 6B), the fourth odd-mode resistor circuit 1270 may include first and second mutual-inductance resistors 272″, 272″′ electrically coupled in parallel between adjacent bond pad segments (e.g., between input bond pad segments 252-1, 252-2). In contrast with the first odd-mode resistor circuits 270, 270′, the fourth odd-mode resistor circuit 1270 is directly connected to the adjacent bond pad segments 252-1, 252-2, rather than being electrically coupled to the bond pad segments through conductive vias (e.g., conductive vias 258, 259, FIGS. 4, 5A, 5B, 6A, 6B). The direct connection of the fourth odd-mode resistor circuits 1270 to the bond pad segments 252-1, 252-2 is possible because the first and second mutual-inductance resistors 272″, 262″′ are positioned at or on the top surface 204 of the semiconductor die 202, rather than below the top surface 204.

Specifically, each first and second mutual-inductance resistor 272″, 272″′ includes a length of resistor material that extends between and electrically connects to a first terminal 273″, 273″′ (or first end) of the resistor 272″, 272″′ and a second terminal 274″, 274″′ (or second end) of the resistor 272″, 272′″. As indicated above and shown in FIGS. 13-15, the first terminal 273″, 273″′ may be directly physically and electrically connected to a first bond pad segment 252-1, and the second terminal 274″, 274″′ may be directly physically and electrically connected to a second bond pad segment 252-2.

In the embodiments of FIGS. 13-15, the length of resistor material forming each resistor 272″, 272″′ may be a patterned portion of a conductive layer that is deposited and patterned during the BEOL process of fabricating the FET 1200. In one or more embodiments, the resistors 272″, 272″′ may be formed from one or more layers of other resistor materials that are separately deposited and patterned during the BEOL process. For example, as best seen in FIGS. 14 and 15, resistors 272″, 272″′ are formed from patterned portions of a separately-deposited conductive material 1413 on the highest dielectric layer 219 (i.e., layer 1413 is a different layer than conductive layer 215).

Resistors 272″, 272″′ are desirably formed from a conductive material that has a relatively-high resistivity (e.g., a material characterized by a resistivity of 0.40 Ω·m or more, or by a resistivity of 1.0μΩ·m or more), when compared with the resistivity of other metals (e.g., copper, aluminum), which may be used to form interconnects and vias in the BEOL process. For example, resistors 272″, 272″′ may be formed from one or more materials selected from Nichrome, TiW, TiWN, a cobalt alloy, semiconductor material, or other suitable materials.

Referring to FIG. 13, the first mutual-inductance resistor 272″ includes a first mutual-inductance structure 275″ that includes a first elongated resistor segment 276″ and a second elongated resistor segment 277″, which are arranged next to each other and physically oriented in parallel across a non-conductive gap 284. First ends of the first and second resistor segments 276″, 277″ are electrically coupled to the first and second terminals 273″, 274″, respectively, and thus are electrically coupled to the first and second input bond pad segments 252-1, 252-2. Second ends of the first and second resistor segments 276″, 277″ are electrically coupled together through a transverse resistor segment 278″. Accordingly, the first and second resistor segments 276″, 277″ are electrically coupled in series between the first and second terminals 273″, 274″. Optionally, the first ends of the resistor segments 276″, 277″ are coupled to the first and second terminals 273″, 274″ through angled resistor segments 279″, which may be used to transition between the distance (pitch) between the first and second input bond pad segments 252-1, 252-2 and a desired width of gap 284.

Similarly, the second mutual-inductance resistor 272″′ includes a second mutual-inductance structure 275″′ that includes a third elongated resistor segment 276″′ and a fourth elongated resistor segment 277′″, which are arranged next to each other and physically oriented in parallel across a non-conductive gap 284′. First ends of the third and fourth resistor segments 276′″, 277″′ are electrically coupled to the first and second terminals 273′″, 274′″, respectively, and thus are electrically coupled to the first and second input bond pad segments 252-1, 252-2. The third and fourth resistor segments 276′″, 277″′ are electrically coupled in series between the first and second terminals 273′″, 274′″. Optionally, the first ends of the resistor segments 276′″, 277″′ are coupled to the first and second terminals 273′″, 274″′ through angled resistor segments 279′″, which may be used to transition between the distance (pitch) between the first and second input bond pad segments 252-1, 252-2 and a desired width of gap 284′. Second ends of the third and fourth resistor segments 276′″, 277″′ are electrically coupled together through a transverse resistor segment 278′″.

According to one or more embodiments, the first and second mutual-inductance resistors 272″, 272″′ are mirror images of each other, and accordingly, the fourth odd-mode resistor circuit 1270 is symmetrical about a line of symmetry (not numbered) that is parallel with the first and second sides 205, 206 of the semiconductor die 202. The first and second mutual-inductance resistors 272″, 272″′ are characterized by various dimensions, which may be substantially the same as the dimensions discussed for resistors 272, 272′. According to one or more embodiments, the widths of gaps 284, 284′ should be sufficiently small so that the odd-mode resistor circuits 1270 are characterized by a significant negative mutual inductance during operation. According to one or more embodiments, the resistor value of each of the first and second mutual-inductance resistors 272″, 272″′ is in a range of about 4 ohms to about 12 ohms, and the total resistance value for the first and second mutual-inductance resistors 272″, 272″′ is in a range of about 2 ohms to about 6 ohms. In other embodiments, the resistor values (or total resistance value) may be smaller or larger.

The total resistance value of each of the first odd-mode resistor circuits 1270 is selected to ensure that the circuits 1270 effectively dampen odd-mode loop currents within FET 1200. As mentioned previously, the parasitic inductance of any odd-mode resistor circuit negatively affects the odd-mode stability of a FET. Accordingly, there is a desire to provide an odd-mode resistor circuit with sufficiently high resistance to effectively dampen the odd-mode loop currents while having a sufficiently low parasitic inductance to ensure adequate odd-mode stability. The first odd-mode resistor circuits 1270 achieve this balance by providing multiple paths of resistance through each of the first odd-mode resistor circuits 1270. By providing each odd-mode resistor circuit 1270 with two mutual-inductance resistors 272″, 272″′ that are electrically coupled in parallel, the parasitic inductance of each odd-mode resistor circuit 1270 is about half of what it would be if only a single resistor (with an equivalent resistance) were used. Utilizing odd-mode resistor circuits 1270 with significantly reduced parasitic inductance has a beneficial effect on the odd-mode stability of FET 1200.

Referring next to FIG. 16, a side, cross-sectional view is illustrated of the fifth odd-mode resistor circuit 1290 of FIG. 12 through line 16-16. Referring to both FIGS. 12 and 16, the fifth odd-mode resistor circuit 1290 includes first and second parallel-coupled resistors 294″, 294″′ electrically coupled between adjacent bond pad segments (e.g., between output bond pad segments 262-1, 262-2). As mentioned above, each of the fifth odd-mode resistor circuits 1290 are electrically coupled between each pair of adjacent output bond pad segments (e.g., adjacent segments 262-1 and 262-2 or adjacent segments 262-2 and 262-3). The fifth odd-mode resistor circuits 1290 may be located within the drain-side inactive area 260. According to one or more embodiments, each fifth odd-mode resistor circuit 1290 is more specifically positioned within the build-up structure 212 in the drain-side inactive area 260 within the non-conductive gap 264 between adjacent output bond pad segments.

In contrast with the odd-mode resistor circuits 290, 290′ (FIGS. 7, 8A, 8B, 9A, 9B), the fifth odd-mode resistor circuit 1290 is directly connected to the adjacent bond pad segments 262-1, 262-2, rather than being electrically coupled to the bond pad segments through conductive vias (e.g., conductive vias 288, 289, FIGS. 7, 8A, 8B, 9A, 9B). The direct connection of the fifth odd-mode resistor circuits 1290 to the bond pad segments 262-1, 262-2 is possible because the first and second parallel-coupled resistors 294″, 294″′ are positioned at or on the top surface 204 of the semiconductor die 202, rather than below the top surface 204.

Specifically, each first and second parallel-coupled resistor 294″, 294″′ includes a length of resistor material that extends between and electrically connects to a first terminal 291″ (or first end) of the resistor 294″, 294″′ and a second terminal 292″ (or second end) of the resistor 294″, 294′″. As indicated above and shown in FIG. 16, the first terminals 291″ may be directly physically and electrically connected to a first bond pad segment 262-1, and the second terminals 292″ may be directly physically and electrically connected to a second bond pad segment 262-2.

In the embodiment of FIGS. 12 and 16, the length of resistor material forming each resistor 294″, 294″′ may be a patterned portion of a conductive layer that is deposited and patterned during the BEOL process of fabricating the FET 200. In some embodiments, the resistors 294, 294′ may be formed from the same material as one of the conductive layers 213, 214. Alternatively, in other embodiments, the resistors 294, 294′ may be formed from layers of other resistor materials that are separately deposited and patterned during the BEOL process. In one or more embodiments, the resistors 294″, 294″′ may be formed from one or more layers of other resistor materials that are separately deposited and patterned during the BEOL process. For example, as best seen in FIG. 16, resistors 294″, 294″′ are formed from patterned portions of a separately-deposited conductive material 1613 on the highest dielectric layer 219 (i.e., layer 1613 is a different layer than conductive layer 215). According to one or more alternate embodiments, rather than being formed from conductive layer 1613, each of the first and second parallel-coupled resistors 294″, 294″′ may include a discrete, surface mount resistor device with terminals that are connected (e.g., soldered to) the bond pad segments 262-1, 262-2.

Resistors 294″, 294″′ are desirably formed from a conductive material that has a relatively-high resistivity (e.g., a material characterized by a resistivity of 0.40 Ω·m or more, or by a resistivity of 1.0μΩ·m or more), when compared with the resistivity of other metals (e.g., copper, aluminum), which may be used to form interconnects and vias in the BEOL process. For example, resistors 294, 294′ may be formed from one or more materials selected from Nichrome, TiW, TiWN, a cobalt alloy, semiconductor material, or other suitable materials.

Referring to FIG. 12, the first parallel-coupled resistor 294″ includes a first elongated resistor segment (not separately numbered), which extends between and electrically connects to the adjacent bond pad segments 262-2 and 262-3. Similarly, the second parallel-coupled resistor 294″′ includes a second elongated resistor segment (not separately numbered), which extends between and electrically connects the adjacent segments 262-2 and 262-3. The first and second parallel-coupled resistors 294″, 294″′ (and particularly, the first and second elongated segments of resistor materials) are arranged next to each other, and are physically oriented in parallel across a non-conductive gap 293.

According to one or more embodiments, the first and second parallel-coupled resistors 294″, 294″′ are substantially identical to each other. The first and second parallel-coupled resistors 294″, 294″′ are characterized by various dimensions, which may be substantially the same as the dimensions discussed for resistors 294, 294′. According to one or more embodiments, the resistor value of each of the first and second parallel-coupled resistors 294″, 294″′ is in a range of about 14 ohms to about 30 ohms, and the total resistance value for the first and second parallel-coupled resistors 294″, 294″′ is in a range of about 7 ohms to about 15 ohms. In other embodiments, the resistor values (or total resistance value) may be smaller or larger.

During operation of FET 1200, the first and second parallel-coupled resistors 294″, 294″′ are configured to carry current in the same direction. However, by using two parallel-coupled resistors 294″, 294″′ to achieve the desired effective resistance, the overall parasitic inductance of the odd-mode resistor circuit 1290 is about half of what it would be if a single odd-mode resistor with the same effective resistance were used. Accordingly, including two parallel-coupled resistors 294″, 294″′ essentially functions to reduce the effective inductance (parasitic inductance) of the odd-mode resistor circuit 1290, which in turn may improve the odd-mode stability of the FET 1200.

FIGS. 2-4, 12, and 13 show several example embodiments of low-inductance odd-mode resistor circuits 270, 1270, each with two mutual-inductance odd-mode resistors 272, 272′, 272″, 272″′ electrically coupled in parallel and symmetrically-arranged between adjacent bond pad segments (e.g., bond pad segments 252-1, 252-2). Further, each of the odd-mode resistors 272, 272′, 272″, 272″′ includes a mutual-inductance structure 275, 275′, 275″, 275″′ that includes first and second elongated resistor segments 276, 276′, 276″, 276′″, 277, 277′, 277″, 277″′ which are arranged next to each other and physically oriented in parallel across a non-conductive gap 284, 284′. The odd-mode resistors 272, 272′, 272″, 272″′ also include transverse resistor segments 278, 278′, 278″, 278″′ and, optionally, angled resistor segments 279, 279′, 279″, 279′″. Accordingly, the first and second resistor segments 276, 277 are electrically coupled in series between the first and second terminals 273, 274.

The scope of the inventive subject matter also incorporates odd-mode resistors with different but similar mutual-inductance structures. For example, FIGS. 17-19 are top views of various additional embodiments of odd-mode resistor circuits 1770, 1870, 1970, each with one or more mutual-inductance structures 1775, 1875, 1975.

Referring first to FIG. 17, odd-mode resistor circuit 1770 is similar to odd-mode resistor circuits 270, 1270, 1270 (FIGS. 4, 5A, 5B, 13-15), except that odd-mode resistor circuit 1770 includes only one odd-mode resistor 1772, rather than two odd-mode resistors (FIGS. 4, 13) that are electrically coupled in parallel. Similar to the previously-described odd-mode resistors, however, odd-mode resistor 1772 also includes first and second elongated resistor segments 1776, 1777 which are arranged next to each other and physically oriented in parallel across a non-conductive gap 1784. Further, first ends of the resistor segments 1776, 1777 are coupled to first and second terminals 1773, 1774 through angled resistor segments 1779, and second ends of the resistor segments 1776, 1777 are coupled together through a transverse resistor segment 1778. Various alternate embodiments of odd-mode resistor circuit 1770 could be implemented using conductive layer(s) that are located at or below the top surface of a FET (e.g., FET 200, 1200).

Referring next to FIG. 18, odd-mode resistor circuit 1870 is similar to odd-mode resistor circuit 1770 (FIG. 17), except that odd-mode resistor 1872 has a simpler design than odd-mode resistor 1772, and does not include angled resistor segments (e.g., segments 1779). Similar to the previously-described odd-mode resistors, however, odd-mode resistor 1872 also includes first and second elongated resistor segments 1876, 1877 which are arranged next to each other and physically oriented in parallel across a non-conductive gap 1884. Further, first ends of the resistor segments 1876, 1877 are coupled to first and second terminals 1873, 1874, and second ends of the resistor segments 1876, 1877 are coupled together through a transverse resistor segment 1878. Again, various alternate embodiments of odd-mode resistor circuit 1870 could be implemented using conductive layer(s) that are located at or below the top surface of a FET (e.g., FET 200, 1200). In addition, an alternate embodiment of odd-mode resistor circuit 1870 may include a second odd-mode resistor electrically coupled in parallel with resistor 1872, in a manner similar to odd-mode resistor circuits 270, 1270, 1270.

Referring next to FIG. 19, odd-mode resistor circuit 1970 also is similar to odd-mode resistor circuit 1770 (FIG. 17), except that odd-mode resistor 1972 includes more than two resistor segments and mutual-inductance structures. More specifically, odd-mode resistor 1972 includes first, second, third, and fourth elongated resistor segments 1976, 1977, 1978, 1979 which are arranged next to each other and physically oriented in parallel. The first and second resistor segments 1976, 1977 are positioned across a first non-conductive gap 1984, the second and third resistor segments 1977, 1978 are positioned across a second non-conductive gap 1984′, and the third and fourth resistor segments 1978, 1979 are positioned across a third non-conductive gap 1984″. During operation, each pair of adjacent resistor segments carries current in opposite directions, and thus negative mutual coupling occurs between the signals carried along each pair of adjacent resistor segments. Again, various alternate embodiments of odd-mode resistor circuit 1970 could be implemented using conductive layer(s) that are located at or below the top surface of a FET (e.g., FET 200, 1200). In addition, an alternate embodiment of odd-mode resistor circuit 1970 may include a second odd-mode resistor electrically coupled in parallel with resistor 1972, in a manner similar to odd-mode resistor circuits 270, 1270, 1270.

Various types of odd-mode resistor circuits (270, 270′, 1270, 290, 290′, 290″, 1290), have been discussed above. It should be understood that each type of odd-mode resistor circuit (270, 270′, 1270, 290, 290′, 290″, 1290) could be used at the input and/or the output of a FET, and the combination of odd-mode resistor circuit types previously discussed should not be construed as limiting. For example, referring again briefly to FIG. 2, a FET 200 is illustrated that includes odd-mode resistor circuits 270, 270′ with mutual-inductance resistors that are electrically coupled between adjacent segments 252-1 through 252-6 of a segmented input bond pad 252, and FET 200 also includes odd-mode resistor circuits 290, 290′ with parallel-coupled resistors that are electrically coupled in parallel between adjacent segments 262-1 through 262-3 of a segmented output bond pad 262.

FIGS. 20-22 are provided as non-limiting additional examples of FETs 2000, 2100, 2200 that include different configurations of odd-mode resistor circuit types. Each of FIGS. 20-22 show a top view of a FET 2000, 2100, 2200, respectively, with segmented gate and drain bond pads 252, 262 and various other example combinations of low-inductance odd-mode resistor circuits, which have been described previously. It should be understood that FIGS. 20-22 show just three additional example combinations of previously-described, low-inductance odd-mode resistor circuits. The illustrated examples are not meant to be limiting, and FETs with other combinations of low-inductance odd-mode resistor circuits are intended to be included in the scope of the inventive subject matter.

Except for the combinations of low-inductance odd-mode resistor circuits, FETs 2000, 2100, 2200 are substantially similar to FETs 200, 1200. More particularly, FETs 2000, 2100, 2200 have many features that are identical or substantially similar to features discussed above with reference to the various embodiments of FETs 200, 1200 (FIGS. 2, 3, 12). For conciseness, the identical or substantially similar features between FETs 200, 1200 and FETs 2000, 2100, 2200 are not repeated here. Instead, the identical of substantially similar features are indicated with identical reference numbers between the embodiments of FIGS. 2, 3, and 12 and the embodiments of FIGS. 20-22. All of the details described above for features in FIGS. 2, 3, and 12 that have the same reference numbers as features in FIGS. 20-22 are incorporated into this description of FIGS. 20-22.

As a brief summary, each of FETs 2000, 2100, 2200 may employ a multi-layer circuit configured integrally formed within a semiconductor die 202. The semiconductor die 202 includes a base semiconductor substrate (e.g., base semiconductor substrate 208) and a build-up structure (e.g., build-up structure 212) coupled to a top surface of the base substrate. The base semiconductor substrate may be formed, for example, from bulk or composite semiconductor materials (e.g., Si, SiC, GaN, GaAs, SoI, GaN-on-insulator, or other suitable materials). A conductive layer (e.g., layer 210) is coupled to a bottom surface of the base semiconductor substrate.

The semiconductor die 202 has a centrally located active area 229, a gate-side inactive area 250 between the active area 229 and the first side of the die 202, and a drain-side inactive area 260 between the active area 229 and the second side of the die 202. The active area 229 of die 202 includes a plurality of elongated transistor fingers (e.g., fingers 230), which extend between the gate-side and drain-side inactive areas 250, 260, and which are arranged in parallel with each other over the width of the die 202. Details of the transistor fingers 230 described above in conjunction with FIGS. 2 and 3 are incorporated here.

In the gate-side inactive area 250, each of FETs 2000, 2100, 2200 includes a segmented input bond pad 252 proximate the first side of the die 202. Similarly, in the drain-side inactive area 260, each of FETs 2000, 2100, 2200 includes a segmented output bond pad 262 proximate the second side of the die 202. The segmented input bond pad 252 includes a plurality of input bond pad segments 252-1, 252-2, 252-3, 252-4, 252-5, 252-6, and a non-conductive gap (e.g., gap 254) is present between sets of adjacent input bond pad segments. Similarly, the segmented output bond pad 262 includes a plurality of output bond pad segments 262-1, 262-2, 262-3, and a non-conductive gap (e.g., gap 264) is present between sets of adjacent output bond pad segments.

Referring to FIG. 20, according to one or more embodiments, input-side, odd-mode resistor circuits 270, 270′, and/or 1270 (each including one or more mutual-inductance resistors 272, 272′, 272″, 272′″, FIGS. 4, 13) are electrically coupled between each pair of adjacent input bond pad segments 252-1 through 252-6 within the gate-side inactive area 250 (e.g., within the build-up structure in the gate-side inactive area 250 underneath or within the non-conductive gap between adjacent input bond pad segments).

In addition, according to one or more further embodiments, output-side, odd-mode resistor circuits 270, 270′, and/or 1270 (each including one or more mutual-inductance resistors 272, 272′, 272″, 272′″, FIGS. 4, 12, 13) are electrically coupled between each pair of adjacent output bond pad segments 262-1 through 262-3 within the drain-side inactive area 260 (e.g., within the build-up structure in the drain-side inactive area 260 underneath or within the non-conductive gap between adjacent output bond pad segments). FIG. 20 illustrates that an embodiment of a FET (e.g., FET 2000) may include odd-mode resistor circuits 270, 270′, 1270 with mutual-inductance resistors (e.g., resistors 272, 272′, 272″, 272′″, FIGS. 4, 13) coupled to either or both of the input and/or output bond pad segments 252-1 through 252-6, 262-1 through 262-3 of the FET. It should be noted here that other types of mutual-inductance resistors (e.g., resistors 1772, 1872, 1972, FIGS. 17-19) also or alternatively may be used in FET 2000.

Referring now to FIG. 21, according to one or more embodiments, input-side, odd-mode resistor circuits 290, 290′, and/or 1290 (each including one or more parallel-coupled resistors 294, 294′, 294″, 294′″, FIGS. 7, 12, 16) are electrically coupled between each pair of adjacent input bond pad segments 252-1 through 252-6 within the gate-side inactive area 250 (e.g., within the build-up structure in the gate-side inactive area 250 underneath or within the non-conductive gap between adjacent input bond pad segments).

In addition, according to one or more further embodiments, output-side, odd-mode resistor circuits 290, 290′, and/or 1290 (each including one or more parallel-coupled resistors 294, 294′, 294″, 294′″, FIGS. 7, 12, 16) are electrically coupled between each pair of adjacent output bond pad segments 262-1 through 262-3 within the drain-side inactive area 260 (e.g., within the build-up structure in the drain-side inactive area 260 underneath or within the non-conductive gap between adjacent output bond pad segments). FIG. 21 illustrates that an embodiment of a FET (e.g., FET 2100) may include odd-mode resistor circuits 290, 290′, 1290 with parallel-coupled resistors (e.g., resistors 294, 294′, 294″, 294′″, FIGS. 7, 12, 16) coupled to either or both of the input and/or output bond pad segments 252-1 through 252-6, 262-1 through 262-3 of the FET.

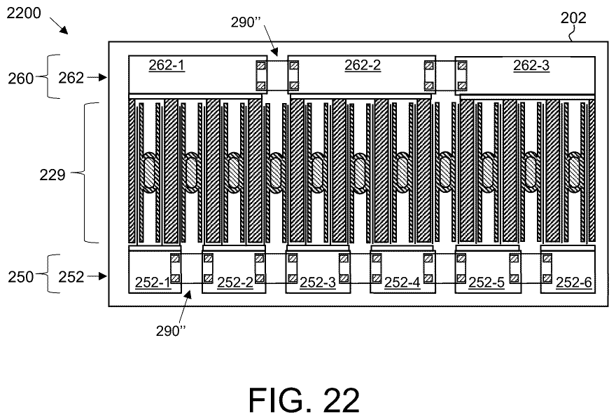

Finally, referring now to FIG. 22, according to one or more embodiments, input-side, odd-mode resistor circuits 290″ (each including one or more 2^{N}-terminal resistors 1094, FIGS. 10, 11A, 11B) are electrically coupled between each pair of adjacent input bond pad segments 252-1 through 252-6 within the gate-side inactive area 250 (e.g., within the build-up structure in the gate-side inactive area 250 underneath or within the non-conductive gap between adjacent input bond pad segments).

In addition, according to one or more further embodiments, output-side, odd-mode resistor circuits 290″ (each including one or more 2^{N}-terminal resistors 1094, FIGS. 10, 11A, 11B) are electrically coupled between each pair of adjacent output bond pad segments 262-1 through 262-3 within the drain-side inactive area 260 (e.g., within the build-up structure in the drain-side inactive area 260 underneath or within the non-conductive gap between adjacent output bond pad segments). FIG. 22 illustrates that an embodiment of a FET (e.g., FET 2200) may include odd-mode resistor circuits 290″ with 2^{N}-terminal resistors (e.g., resistors 1094, FIGS. 10, 11A, 11B) coupled to either or both of the input and/or output bond pad segments 252-1 through 252-6, 262-1 through 262-3 of the FET.

An embodiment of a transistor includes a semiconductor die with a first side and a second side opposite the first side, a first transistor finger and a second transistor finger formed in an active area of the semiconductor die, a first bond pad segment formed in the semiconductor die and electrically coupled to the first transistor finger, and a second bond pad segment formed in the semiconductor die, electrically coupled to the second transistor finger, and adjacent to the first bond pad segment, where a first non-conductive gap is present between the first and second bond pad segments. The transistor embodiment also includes a first odd-mode resistor circuit electrically coupled to the first and second bond pad segments, where the first odd-mode resistor circuit has a first resistor segment and a second resistor segment, and wherein the first and second resistor segments are arranged next to each other and oriented in parallel.

According to one or more further embodiments, the first odd-mode resistor circuit further includes a first terminal electrically coupled to the first bond pad segment, and a second terminal electrically coupled to the second bond pad segment, where the first and second resistor segments are electrically coupled in series between the first and second terminals, and the first and second resistor segments have length dimensions that are perpendicular to the first and second sides of the semiconductor die. According to one or more further embodiments, the first and second resistor segments are separated across a second non-conductive gap that has a gap width dimension that is sufficiently small so that the first odd-mode resistor circuit is characterized by a negative mutual inductance.

According to one or more further embodiments, the first odd-mode resistor circuit further includes a first terminal connecting the first resistor segment to the first bond pad segment, a second terminal connecting the first resistor segment to the second bond pad segment, a third terminal connecting the second resistor segment to the first bond pad segment, and a fourth terminal connecting the second resistor segment to the second bond pad segment, where the first and second resistor segments are electrically coupled in parallel between the first and second bond pad segments. According to one or more further embodiments, the first and second resistor segments are separated by a second non-conductive gap. According to one or more alternative further embodiments, the first and second resistor segments form portions of a single mass of resistor material.

The instant disclosure is provided to further explain in an enabling fashion at least one embodiment in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It should be understood that the use of relational terms, if any, such as first and second, top and bottom, and the like are used solely to distinguish one from another entity or action without necessarily requiring or implying any actual such relationship or order between such entities or actions. Furthermore, some of the figures may be illustrated using various shading and/or hatching to distinguish the different elements produced within the various structural layers. These different elements within the structural layers may be produced utilizing current and upcoming microfabrication techniques of depositing, patterning, etching, and so forth. Accordingly, although different shading and/or hatching is utilized in the illustrations, the different elements within the structural layers may be formed out of the same material.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A transistor comprising:
a semiconductor die with a first side and a second side opposite the first side;
a first transistor finger and a second transistor finger formed in an active area of the semiconductor die;
a first bond pad segment formed in the semiconductor die and electrically coupled to the first transistor finger;
a second bond pad segment formed in the semiconductor die and electrically coupled to the second transistor finger, wherein the second bond pad segment is adjacent to the first bond pad segment, and a first non-conductive gap is present between the first and second bond pad segments; and
a first odd-mode resistor circuit electrically coupled to the first and second bond pad segments, wherein the first odd-mode resistor circuit has a first resistor segment and a second resistor segment, and wherein the first and second resistor segments are arranged next to each other and oriented in parallel.

2. The transistor of claim 1, wherein:
the first odd-mode resistor circuit further includes
a first terminal electrically coupled to the first bond pad segment, and
a second terminal electrically coupled to the second bond pad segment;
the first and second resistor segments are electrically coupled in series between the first and second terminals; and
the first and second resistor segments have length dimensions that are perpendicular to the first and second sides of the semiconductor die.

3. The transistor of claim 2, wherein:
the first and second resistor segments are separated across a second non-conductive gap that has a gap width dimension that is sufficiently small so that the first odd-mode resistor circuit is characterized by a negative mutual inductance.

4. The transistor of claim 2, wherein:
the first resistor segment is configured to carry current in a first direction and the second resistor segment is configured to carry the current in a second direction that is opposite the first direction.

5. The transistor of claim 2, wherein:
the first odd-mode resistor circuit further includes a first transverse resistor segment connected between the first and second resistor segments.

6. The transistor of claim 2, wherein the first odd-mode resistor circuit further comprises:
a third resistor segment and a fourth resistor segment, wherein
the third and fourth resistor segments are arranged next to each other and oriented in parallel,
the third and fourth resistor segments are electrically coupled in series between the first and second terminals, and
the third and fourth resistor segments have length dimensions that are perpendicular to the first and second sides of the semiconductor die.

7. The transistor of claim 6, wherein:
the first and second resistor segments extend from the first and second terminals towards the first side of the semiconductor die; and
the third and fourth resistor segments extend from the first and second terminals towards the second side of the semiconductor die.

8. The transistor of claim 7, wherein the first and second resistor segments are symmetrical with the third and fourth resistor segments about a line that is parallel with the first and second sides of the semiconductor die.

9. The transistor of claim 1, wherein the first odd-mode resistor circuit further comprises:
a first terminal connecting the first resistor segment to the first bond pad segment;
a second terminal connecting the first resistor segment to the second bond pad segment;
a third terminal connecting the second resistor segment to the first bond pad segment; and
a fourth terminal connecting the second resistor segment to the second bond pad segment, and wherein
the first and second resistor segments are electrically coupled in parallel between the first and second bond pad segments.

10. The transistor of claim 9, wherein the first and second resistor segments are separated by a second non-conductive gap.

11. The transistor of claim 9, wherein the first and second resistor segments form portions of a single mass of resistor material.

12. The transistor of claim 1, wherein the first and second resistor segments are positioned within the first non-conductive gap.

13. The transistor of claim 1, wherein:
the semiconductor die includes a base semiconductor substrate and a build-up structure on the base semiconductor substrate that defines a top surface of the semiconductor die, and
the first and second resistor segments are formed from a portion of a layer of resistor material within the build-up structure and below the top surface of the semiconductor die.

14. The transistor of claim 1, wherein:
the semiconductor die includes a base semiconductor substrate and a build-up structure on the base semiconductor substrate that defines a top surface of the semiconductor die, and
the first and second resistor segments are formed from a portion of a layer of resistor material at the top surface of the semiconductor die.

15. The transistor of claim 1, wherein:
the semiconductor die includes a base semiconductor substrate and a build-up structure on the base semiconductor substrate that defines a top surface of the semiconductor die, and
the first and second resistor segments form portions of one or more surface-mount devices coupled to the top surface of the semiconductor die.

16. The transistor of claim 1, wherein the first and second resistor segments are formed from a portion of a layer of resistor material, and the layer of resistor material is selected from a group of materials consisting of Nichrome (Ni, Fe, Cr alloy), titanium tungsten (TiW), titanium tungsten nitride (TiWN), a cobalt alloy, and semiconductor material.

17. The transistor of claim 1, wherein:
the first transistor finger includes a first gate structure, a first drain structure, and a first source structure, and
the second transistor finger includes a second gate structure, a second drain structure, and a second source structure.

18. The transistor of claim 17, wherein:
the first and second bond pad segments form portions of a segmented gate bond pad in a gate-side inactive area between the active area and the first side of the semiconductor die,
the first bond pad segment is electrically coupled to the first gate structure of the first transistor finger, and
the second bond pad segment is electrically coupled to the second gate structure of the second transistor finger.

19. The transistor of claim 17, wherein:
the first and second bond pad segments form portions of a segmented drain bond pad in a drain-side inactive area between the active area and the second side of the semiconductor die,
the first bond pad segment is electrically coupled to the first drain structure of the first transistor finger, and
the second bond pad segment is electrically coupled to the second drain structure of the second transistor finger.

20. The transistor of claim 1, further comprising:
a third transistor finger formed in the active area of the semiconductor die;
a third bond pad segment formed in the semiconductor die and electrically coupled to the third transistor finger, wherein the third bond pad segment is adjacent to the second bond pad segment, and a second non-conductive gap is present between the second and third bond pad segments; and
a second odd-mode resistor circuit positioned within the second non-conductive gap and electrically coupled to the second and third bond pad segments, wherein the second odd-mode resistor circuit has a third resistor segment and a fourth resistor segment, and wherein the third and fourth resistor segments are arranged next to each other and oriented in parallel.
